(19) United States
(12) Patent Application Publication
(10) Pub. No.: US 2023/0086426 A1
(43) Pub. Date: Mar. 23, 2023

(54) LASER PROCESSING DEVICE AND LASER PROCESSING METHOD

(71) Applicant: HAMAMATSU PHOTONICS K.K., Hamamatsu-shi, Shizuoka (JP)

(72) Inventors: Katsuhiro KOREMATSU, Hamamatsu-shi, Shizuoka (JP); Takeshi SAKAMOTO, Hamamatsu-shi, Shizuoka (JP)

(73) Assignee: HAMAMATSU PHOTONICS K.K., Hamamatsu-shi, Shizuoka (JP)

(21) Appl. No.: 17/795,309

(22) PCT Filed: Jan. 18, 2021
(86) PCT No.: PCT/JP2021/001509

§ 371 Date: Jul. 26, 2022

(30) Foreign Application Priority Data
Jan. 28, 2020 (JP) 2020-011690

(51) Int. Cl. B23K 26/06

(52) U.S. Cl. CPC B23K 26/0665; B23K 26/0648; B23K 26/0643

(57) ABSTRACT

A laser processing apparatus emits a laser light with a part of a focusing region being on an object to form a modified region along a virtual plane inside the object. The laser processing apparatus includes a support portion, an emission portion that emits the laser light onto the object, a moving mechanism that moves at least one of the support portion and the emission portion so that the part of the focusing region moves along the virtual plane inside the object, and a controller. The emission portion includes a shaping portion that shapes the laser light such that the shape of the part of the focusing region in a plane perpendicular to an optical axis of the laser light has a longitudinal direction. The longitudinal direction is a direction intersecting the direction of movement of the part of the focusing region.

### TECHNICAL FIELD

An aspect of the present invention relates to a laser processing apparatus and a laser processing method.

### BACKGROUND ART

Patent Literature 1 describes a laser processing apparatus including a holding mechanism that holds a work, and a laser emission mechanism that emits a laser light onto the work held by the holding mechanism. In the laser processing apparatus described in Patent Literature 1, the laser emission mechanism having a condenser lens is fixed to a base, and the holding mechanism moves the work along a direction perpendicular to an optical axis of the condenser lens.

### CITATION LIST

### Patent Literature

Patent Literature 1: Japanese Patent No. 5456510

### SUMMARY OF INVENTION

### Technical Problem

Such a laser processing apparatus as described above may be used for a case where a laser light is emitted onto an object to form a modified region along a virtual plane inside the object. In this case, a part of the object is peeled off along the modified region extending over the virtual plane and a crack extending from the modified region, the modified region and crack serving as boundaries. Such peeling processing has become widespread in recent years, leading to, for example, a growing demand for reducing a tack time (reducing an operation time).

An object of an aspect of the present invention is to provide a laser processing apparatus and a laser processing method that allow a reduction in a tact time in a case where a modified region is formed along a virtual plane inside an object.

### Solution to Problem

A laser processing apparatus according to an aspect of the present invention is a laser processing apparatus configured to emit a laser light with a part of a focusing region being on an object to form a modified region along a virtual plane inside the object. The laser processing apparatus includes: a support portion configured to support the object; an emission portion configured to emit the laser light onto the object; a moving mechanism configured to move at least one of the support portion and the emission portion so that the part of the focusing region moves along the virtual plane inside the object; and a controller configured to control the support portion, the emission portion, and the moving mechanism. The emission portion includes a shaping portion configured to shape the laser light such that a shape of the part of the focusing region in a plane along the virtual plane has a longitudinal direction. The longitudinal direction is a direction intersecting a direction of movement of the part of the focusing region.

The inventors, after years of diligent studies, have found that when the modified region is formed along the virtual plane, if the shape of the part of the focusing region of the laser light has the longitudinal direction in the plane along the virtual plane, a crack extending from the modified region along the virtual plane tends to extend in the longitudinal direction. Based on this finding, in the laser processing apparatus according to the aspect of the present invention, the direction intersecting the direction of movement of the part of the focusing region (which will hereinafter be referred to also as a “processing proceeding direction”) is defined as the longitudinal direction. This allows the crack to readily extend in the direction intersecting the processing proceeding direction, thus facilitating spread of the crack along the virtual plane. As a result, for example, even if an interval between reformation spots of the modified region in the direction intersecting the processing proceeding direction is increased, the crack can be caused to spread sufficiently along the virtual plane. Hence a reduction in the tact time can be achieved.

In the laser processing apparatus according to another aspect of the present invention, the longitudinal direction may be a direction tilted at 45° or more against the direction of movement of the part of the focusing region. In this case, spread of the crack along the virtual plane can be further facilitated.

In the laser processing apparatus according to still another aspect of the present invention, the longitudinal direction may be along a direction perpendicular to the direction of movement of the part of the focusing region. In this case, spread of the crack along the virtual plane can be further facilitated.

In the laser processing apparatus according to still another aspect of the present invention, the part of the focusing region may be of a shape with an ellipticity of 0.88 to 0.95. In this case, spread of the crack along the virtual plane can be further facilitated.

In the laser processing apparatus according to still another aspect of the present invention, the controller may move the part of the focusing region relatively along a processing line extending spirally inward from a peripheral edge in the object to form the modified region inside the object. As a result, a part of the object can be peel off precisely along a boundary formed of the modified region extending over the virtual plane and the crack extending from the modified region.

The laser processing apparatus according to still another aspect of the present invention may include an input portion capable of receiving at least one piece of information out of information on a shape of the part of the focusing region, information on a tilt against the direction of movement of the part of the focusing region, and information on setting of the shaping portion, the information being inputted by a user. The controller may control the support portion, the emission portion, and the moving mechanism, based on information input to the input portion. As a result, at formation of the modified region along the virtual plane, at least one piece of information out of the information on the shape of the part of the focusing region, the information on the tilt against the direction of movement of the part of the focusing region, and the information on setting of the shaping portion can be set as desired information.

A laser processing method according to an aspect of the present invention is a laser processing method of emitting a laser light with a part of a focusing region being on to form a modified region along a virtual plane inside the object. The laser processing method includes: an emission step of emitting the laser light onto the object; and a moving step of moving at least one of a support portion and an emission portion, the support portion configured to support the object and the emission portion emitting the laser light onto the object, so that the part of the focusing region moves along the virtual plane inside the object. The emission step includes a shaping step of shaping the laser light such that a shape of the part of the focusing region in a plane perpendicular to an optical axis of the laser light has a longitudinal direction. The longitudinal direction is a direction intersecting the direction of movement of the part of the focusing region.

According to the laser processing method, the direction intersecting the processing proceeding direction is defined as the longitudinal direction. This allows a crack to easily extend in the direction intersecting the processing proceeding direction, thus facilitating spread of the crack along the virtual plane. Hence a reduction in the tact time can be achieved.

### Advantageous Effects of Invention

An aspect of the present invention provides a laser processing apparatus and a laser processing method that allow a reduction in a tact time in a case where a modified region is formed along a virtual plane inside an object.

### BRIEF DESCRIPTION OF DRAWINGS

FIG. 1 is a perspective view of a laser processing apparatus according to an embodiment.

FIG. 2 is a front view of a part of the laser processing apparatus shown in FIG. 1.

FIG. 3 is a front view of a laser processing head of the laser processing apparatus shown in FIG. 1.

FIG. 4 is a side view of the laser processing head shown in FIG. 3.

FIG. 5 is a configuration diagram of an optical system of the laser processing head shown in FIG. 3.

FIG. 6 is a configuration diagram of an optical system of a laser processing head according to a modification.

FIG. 7 is a front view of a part of a laser processing apparatus according to the modification.

FIG. 8 is a perspective view of a laser processing apparatus according to a modification.

FIG. 9 is a plan view schematically showing a configuration of a laser processing apparatus according to a first embodiment.

FIG. 10(a) of FIG. 10 is a plan view of an example of an object.

FIG. 10(b) is a side view of the object shown in FIG. 10(a).

FIG. 11(a) of FIG. 11 is a side view of the object for explaining laser processing according to the embodiment. FIG. 11(b) is a plan view of the object for an explanation continued from the explanation of FIG. 11(a). FIG. 11(c) is a side view of the object shown in FIG. 11(b).

FIG. 12(a) is a side view of the object for an explanation continued from the explanation of FIG. 11(b). FIG. 12(b) is a plan view of the object for an explanation continued from the explanation of FIG. 12(a).

FIG. 13(a) of FIG. 13 is a plan view of the object for an explanation continued from the explanation of FIG. 12(b). FIG. 13(b) is a side view of the object shown in FIG. 13(a). FIG. 13(c) is a side view of the object for an explanation continued from the explanation of FIG. 13(b).

FIG. 14(a) is a plan view of the object for an explanation continued from the explanation of FIG. 13(c). FIG. 14(b) is a side view of the object shown in FIG. 14(a). FIG. 14(c) is a side view of the object for an explanation continued from the explanation of FIG. 14(a). FIG. 14(d) is a side view of the object for an explanation continued from the explanation of FIG. 14(c).

FIG. 15 is a plan view of the object for explaining peeling processing.

FIG. 16(a) depicts a beam shape according to the embodiment. FIG. 16(b) depicts a beam shape according to the modification.

FIG. 17(a) is a plan cross-sectional view of the object for explaining a peeling processing result according to a comparative example in which a laser light of a circular beam shape is used. FIG. 17(b) is a plan cross-sectional view of the object for explaining a peeling processing result according to the embodiment in which a laser light of an elliptical beam shape with a beam rotation angle of 90° is used.

FIG. 18 is a plan view of the object for explaining a branch distance X and a branch distance Y.

FIG. 19(a) is a table showing a relationship between an ellipticity and a beam shape. FIG. 19(b) is a table showing an ellipticity, a beam rotation angle, and a rate of occurrence of a slicing full-cut state.

FIG. 20 depicts a case where an elliptical beam shape has a 0° beam rotation angle.

FIG. 21 depicts a case where an elliptical beam shape has a 600 beam rotation angle.

FIG. 22 depicts an example of a setting screen displayed on a touch panel of a GUI.

FIG. 23 depicts another example of the setting screen displayed on the touch panel of the GUI.

### DESCRIPTION OF EMBODIMENT

An embodiment will hereinafter be described in detail with reference to the drawings. In the drawings, components that are the same or equivalent to each other are denoted by the same reference signs, and redundant description thereof will be omitted.

A basic configuration, advantages, and effects of a laser processing apparatus and modifications of the laser processing apparatus will first be described.

[Configuration of Laser Processing Apparatus]

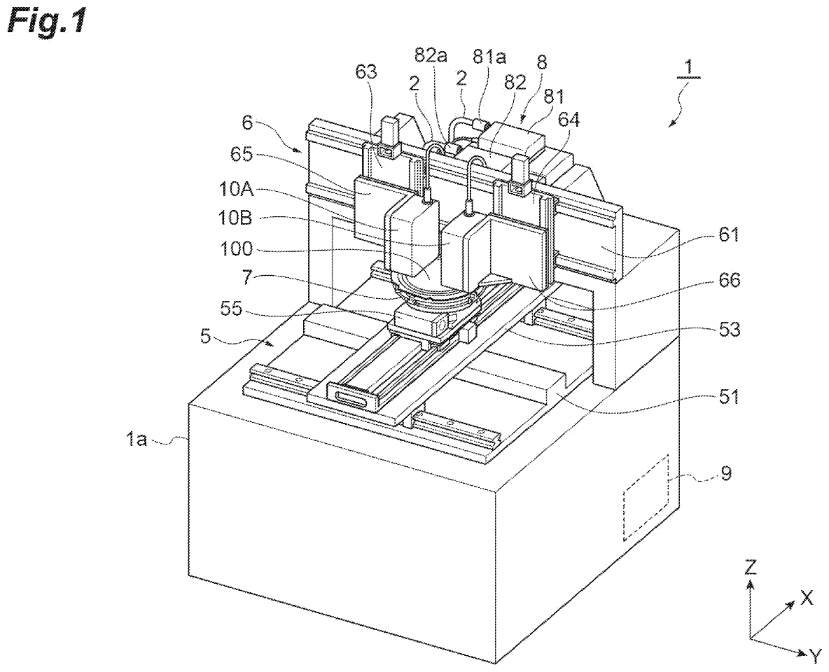

As shown in FIG. 1, a laser processing apparatus 1 includes a plurality of moving mechanisms 5 and 6, a support portion 7, a pair of laser processing heads 10A and 10B, a light source portion 8, and a controller 9. Hereinafter, a first direction is referred to as an X direction, a second direction perpendicular to the first direction is referred to as a Y direction, and a third direction perpendicular to the first direction and the second direction is referred to as a Z direction. In this embodiment, the X direction and the Y direction are horizontal directions, and the Z direction is a vertical direction.

The moving mechanism 5 includes a fixed portion 51, a moving portion 53, and a fitting portion 55. The fixed portion 51 is attached to a device frame 1a. The moving portion 53 is fitted on rails laid on the fixed portion 51, and is therefore able to move along the Y direction. The fitting portion 55 is fitted on rails laid on the moving portion 53, and is therefore able to move along the X direction.

The moving mechanism 6 includes a fixed portion 61, a pair of moving portions 63 and 64, and a pair of fitting portions 65 and 66. The fixed portion 61 is attached to the device frame 1a. The pair of moving portions 63 and 64 are fitted respectively on rails laid on the fixed portion 61, and are each able to independently move along the Y direction. The fitting portion 65 is fitted on rails laid on the moving portion 63, and is therefore able to move along the Z direction. The fitting portion 66 is fitted on rails laid on the moving portion 64, and is therefore able to move along the Z direction. In other words, the pair of fitting portions 65 and 66 can move along the Y direction and the Z direction with respect to the device frame 1a. The moving portions 63 and 64 make up a first horizontally moving mechanism and a second horizontally moving mechanism (horizontally moving mechanism), respectively. The fitting portions 65 and 66 make up a first vertically moving mechanism and a second vertically moving mechanism (vertically moving mechanism), respectively.

The support portion 7 is fitted to a rotating shaft provided on the fitting portion 55 of the moving mechanism 5, and can rotate about an axis, i.e., center line parallel to the Z direction. In other words, the support portion 7 can move along the X direction and along the Y direction as well, and can rotate about the axis, i.e., center line parallel to the Z direction. The support portion 7 supports an object 100. The object 100 is, for example, a wafer.

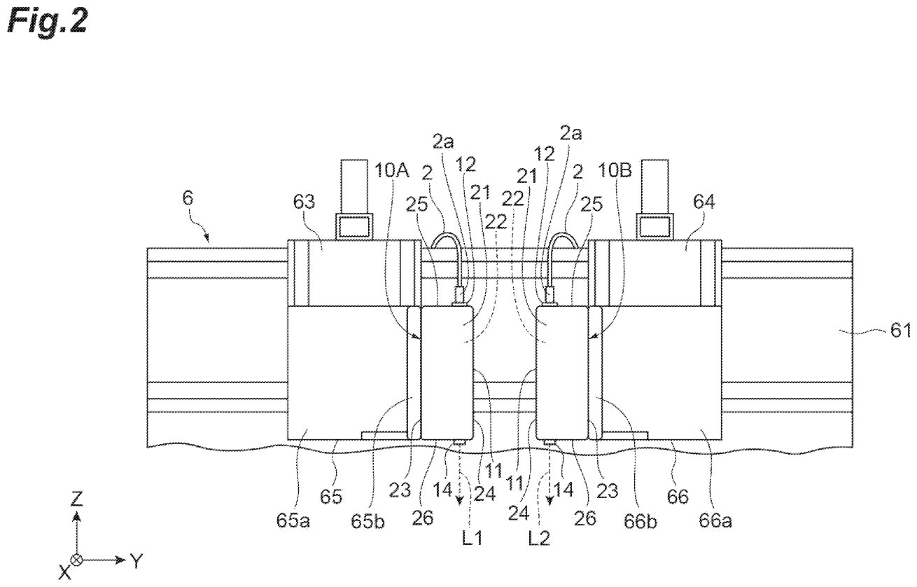

As shown in FIGS. 1 and 2, a laser processing head 10A is fitted to the fitting portion 65 of the moving mechanism 6. The laser processing head 10A in a state of being counter to the support portion 7 in the Z direction emits a laser light L1 (which is referred to also as “first laser light L1”) onto the object 100 supported by the support portion 7. A laser processing head 10B is fitted to the fitting portion 66 of the moving mechanism 6. The laser processing head 10B in a state of being counter to the support portion 7 in the Z direction emits a laser light L2 (which is referred to also as “second laser light L2”) onto the object 100 supported by the support portion 7. The laser processing heads 10A and 10B make up an emission portion.

The light source portion 8 includes a pair of light sources 81 and 82. The light source 81 outputs the laser light L1. The laser light L1 is emitted from an emitting portion 81a of the light source 81, and is led to the laser processing head 10A by an optical fiber 2. The light source 82 outputs the laser light L2. The laser light L2 is emitted from an emitting portion 82a of the light source 82, and is led to the laser processing head 10B by another optical fiber 2.

The controller 9 controls respective components (the support portion 7, the moving mechanisms 5 and 6, the pair of laser processing heads 10A and 10B, the light source portion 8, and the like) of the laser processing apparatus 1. The controller 9 is configured as a computer including a processor, a memory, a storage, and a communication device. At the controller 9, software (program) loaded into the memory or the like is executed by the processor, which controls data reading/writing from/to the memory and storage and communications by the communication device. Through these processes, the controller 9 implements various functions.

An example of processing carried out by the laser processing apparatus 1 configured in the above manner will be described. This example of processing is an example in which, to cut the object 100, a wafer, into a plurality of chips, modified regions are formed inside the object 100 along a lattice pattern of lines.

First, the moving mechanism 5 moves the support portion 7 along the X direction and along the Y direction so that the support portion 7 configured to support the object 100 is set counter to the pair of laser processing heads 10A and 10B in the Z direction. Subsequently, the moving mechanism 5 rotates the support portion 7 about the axis, i.e., center line parallel to the Z direction so that a plurality of lines extending in one direction in the object 100 are set along the X direction in which the lines extend.

Subsequently, the moving mechanism 6 moves the laser processing head 10A along the Y direction so that a focusing point (part of a focusing region) of the laser light L1 is located on one line extending in the one direction. The moving mechanism 6 moves also the laser processing head 10B along the Y direction so that a focusing point of the laser light L2 is located on a different line extending in the one direction. Subsequently, the moving mechanism 6 moves the laser processing head 10A along the Z direction so that the focusing point of the laser light L1 is located inside the object 100. The moving mechanism 6 moves also the laser processing head 10B along the Z direction so that the focusing point of the laser light L2 is located inside the object 100.

Subsequently, the light source 81 outputs the laser light L1, allowing the laser processing head 10A to emit the laser light L1 onto the object 100, as the light source 82 outputs the laser light L2, allowing the laser processing head 10B to emit the laser light L2 onto the object 100. At the same time, the moving mechanism 5 moves the support portion 7 along the X direction so that the focusing point of the laser light L1 moves relatively along the one line extending in the one direction as the focusing point of the laser light L2 moves relatively along the different line extending in the one direction. In this manner, the laser processing apparatus 1 forms modified regions inside the object 100 such that a modified region is formed along each of the plurality of lines extending in the one direction in the object 100.

Subsequently, the moving mechanism 5 rotates the support portion 7 about the axis, i.e., center line parallel to the Z direction so that a plurality of lines extending in a different direction perpendicular to the one direction in the object 100 are set along the X direction in which the lines extend.

Subsequently, the moving mechanism 6 moves the laser processing head 10A along the Y direction so that the focusing point of the laser light L1 is located on one line extending in the different direction. The moving mechanism 6 moves also the laser processing head 10B along the Y direction so that the focusing point of the laser light L2 is located on a different line extending in the different direction. Subsequently, the moving mechanism 6 moves the laser processing head 10A along the Z direction so that the focusing point of the laser light L1 is located inside the object 100. The moving mechanism 6 moves also the laser processing head 10B along the Z direction so that the focusing point of the laser light L2 is located inside the object 100.

Subsequently, the light source 81 outputs the laser light L1, allowing the laser processing head 10A to emit the laser light L1 onto the object 100, as the light source 82 outputs the laser light L2, allowing the laser processing head 10B to emit the laser light L2 onto the object 100. At the same time, the moving mechanism 5 moves the support portion 7 along the X direction so that the focusing point of the laser light L1 moves relatively along the one line extending in the different direction as the focusing point of the laser light L2 moves relatively along the different line extending in the different direction. In this manner, the laser processing apparatus 1 forms modified regions inside the object 100 such that a modified region is formed along each of the plurality of lines extending in the different direction perpendicular to the one direction in the object 100.

In the above example of processing, the light source 81 outputs the laser light L1 penetrative to the object 100, by, for example, a pulse oscillation method, and the light source 82 outputs the laser light L2 penetrative to the object 100, by, for example, a pulse oscillation method. When such laser light focuses inside the object 100, a part corresponding to a focusing point of the laser light absorbs the laser light intensively. As a result, a modified region is formed inside the object 100. A modified region is an area that differs from the surrounding non-modified region in such physical properties as density, refractive index, and mechanical strength. Examples of the modified region include a fusion treatment area, a crack area, a dielectric breakdown area, and a refractive index change area.

When the laser light outputted by the pulse oscillation method is emitted onto the object 100 and the focusing point of the laser light is moved relatively along a line set on the object 100, a plurality of reformed spots are formed along the line, as a row of reformed spots. One reformed spot is formed by being exposed to one pulse of laser light. A row of modified regions is a set of lined up reformed spots. Reformed spots adjacent to each other may be connected to each other or separated from each other, depending on the speed of relative movement of the focusing point of the laser light to the object 100 and on the repetition frequency of the laser light. The shape of lines to be set is not limited to a lattice shape, and may be an annular shape, a linear shape, a curved shape, or a shape created by combining at least some of these shapes.

[Configuration of Laser Processing Head]

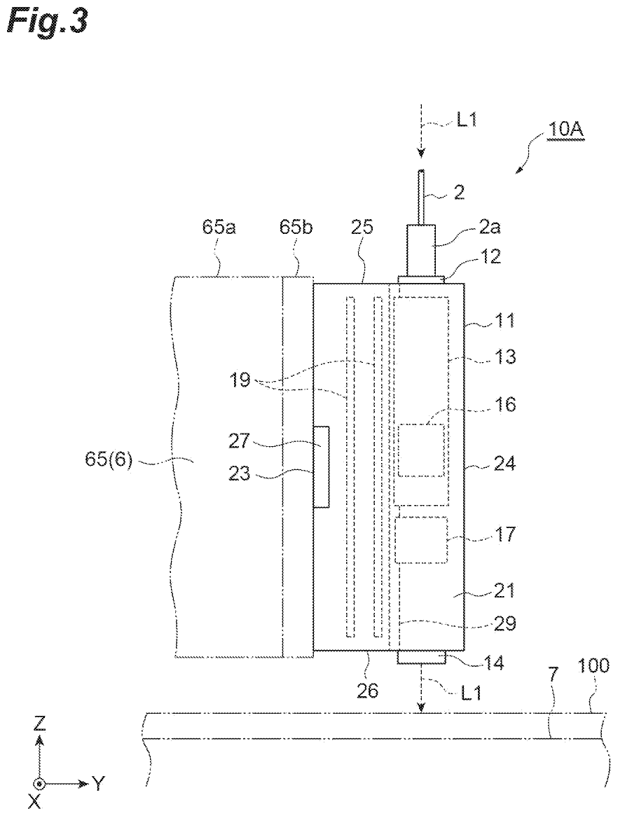

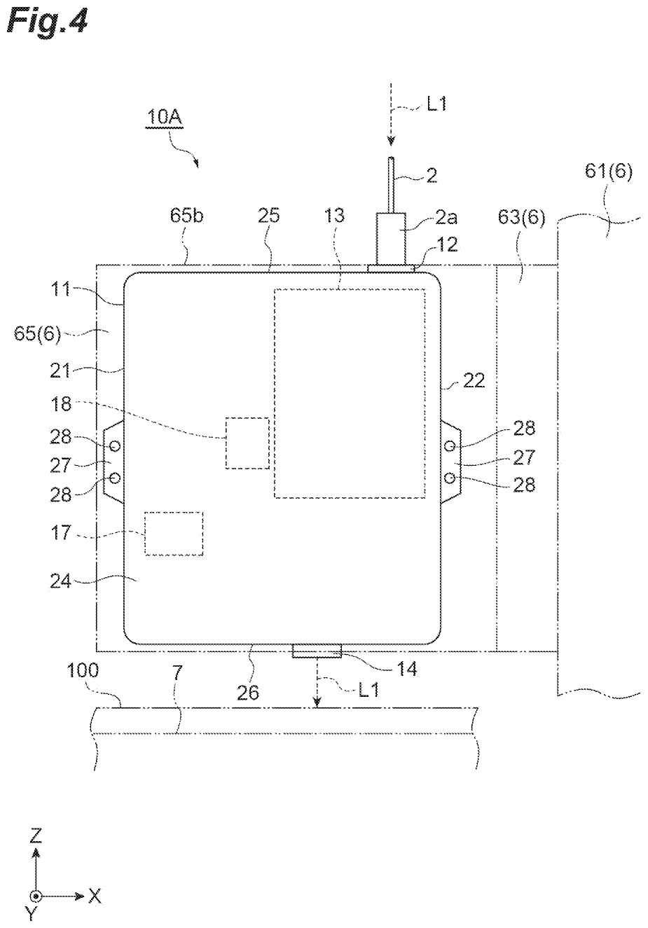

As shown in FIGS. 3 and 4, the laser processing head 10A includes a housing 11, an incident portion 12, an adjuster 13, and a light-condensing portion 14.

The housing 11 has a pair of a first wall 21 and a second wall 22, a pair of a third wall 23 and a fourth wall 24, and a pair of a fifth wall 25 and a sixth wall 26. The first wall 21 and the second wall 22 are counter to each other in the X direction. The third wall 23 and the fourth wall 24 are counter to each other in the Y direction The fifth wall 25 and the sixth wall 26 are counter to each other in the Z direction

The distance between the third wall 23 and the fourth wall 24 is smaller than the distance between the first wall 21 and the second wall 22. The distance between the first wall 21 and the second wall 22 is smaller than the distance between the fifth wall 25 and the sixth wall 26. The distance between the first wall 21 and the second wall 22 may be made equal to the distance between the fifth wall 25 and the sixth wall 26, or may be made larger than the same.

In the laser processing head 10A, the first wall 21 is located opposite to the fixed portion 61 of the moving mechanism 6, while the second wall 22 is located closer to the fixed portion 61. The third wall 23 is located closer to the fitting portion 65 of the moving mechanism 6, while the fourth wall 24 is located opposite to the fitting portion 65 and closer to the laser processing head 10B (see FIG. 2). The fifth wall 25 is located opposite to the support portion 7, while the sixth wall 26 is located closer to the support portion 7.

The housing 11 is configured such that the housing 11 is fitted to the fitting portion 65, with the third wall 23 disposed on the fitting portion 65 of the moving mechanism 6. More specific description is given as follows. The fitting portion 65 has a base plate 65a and a fitting plate 65b. The base plate 65a is fitted on the rails laid on the moving portion 63 (see FIG. 2). The fitting plate 65b is erected on an end of base plate 65a that is closer to the laser processing head 10B (see FIG. 2). The housing 11 is fitted to the fitting portion 65 by screwing bolts 28 to the fitting plate 65b via pedestals 27 as the third wall 23 is kept in contact with the fitting plate 65b. The pedestals 27 are provided on the first wall 21 and the second wall 22, respectively. The housing 11 can be fitted to or removed from the fitting portion 65.

The incident portion 12 is fitted to the fifth wall 25. The incident portion 12 causes the laser light L1 to enter the housing 11. The incident portion 12 is on a side closer to the second wall 22 (one wall side) in the X direction, and is on a side closer to the fourth wall 24 in the Y direction. In other words, the distance between the incident portion 12 and the second wall 22 in the X direction is smaller than the distance between the incident portion 12 and the first wall 21 in the X direction, and the distance between the incident portion 12 and the fourth wall 24 in the Y direction is smaller than the distance between the incident portion 12 and the third wall 23 in the X direction.

The incident portion 12 is configured such that a connection end 2a of the optical fiber 2 can be connected to the incident portion 12. The connection end 2a of the optical fiber 2 is provided with a collimator lens that collimates the laser light L1 coming out of an emission end of the fiber, but is not provided with an isolator that suppresses return light. The isolator is disposed on a part of the fiber, the part being closer to the light source 81 than to the connection end 2a. This arrangement contributes to miniaturization of the connection end 2a, thus contributing to miniaturization of the incident portion 12. It should be noted, however, that the connection end 2a of the optical fiber 2 may be provided with the isolator.

The adjuster 13 is disposed in the housing 11. The adjuster 13 adjusts the incoming laser light L1 from the incident portion 12. Components the adjuster 13 has are mounted on an optical base 29 provided in the housing 11. The optical base 29 is fitted to the housing 11 in such a way as to partition an area inside the housing 11 into a subarea on the third wall 23 side and a subarea on the fourth wall 24 side. Being fitted to the housing 11, the optical base 29 serves as its integral part. The components the adjuster 13 has are mounted on the optical base 29 on the fourth wall 24 side. Details of the components the adjuster 13 has will be described later.

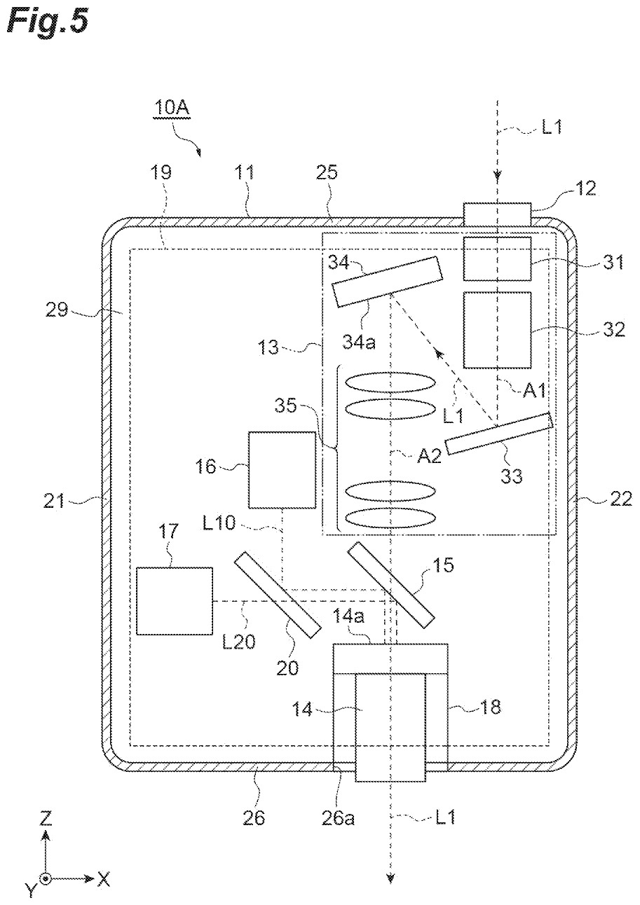

The light-condensing portion 14 is disposed on the sixth wall 26. Specifically, the light-condensing portion 14 is disposed on the sixth wall 26 in such a way that the light-condensing portion 14 is inserted in a hole 26a formed on the sixth wall 26 (see FIG. 5). The light-condensing portion 14 condenses the laser light L1 adjusted by the adjuster 13 and sends the condensed laser light L1 out of the housing 11. The light-condensing portion 14 is on the side closer to the second wall 22 (one wall side) in the X direction, and is on the side closer to the fourth wall 24 in the Y direction. In other words, the distance between the light-condensing portion 14 and the second wall 22 in the X direction is smaller than the distance between the light-condensing portion 14 and the first wall 21 in the X direction, and the distance between the light-condensing portion 14 and the fourth wall 24 in the Y direction is smaller than the distance between the light-condensing portion 14 and the third wall 23 in the X direction.

As shown in FIG. 5, the adjuster 13 includes an attenuator 31, a beam expander 32, and a mirror 33. The incident portion 12, and the attenuator 31, the beam expander 32, and the mirror 33 of the adjuster 13 are aligned on a straight line (first straight line) A1 extending along the Z direction. The attenuator 31 and the beam expander 32 are arranged between the incident portion 12 and the mirror 33 on the straight line A1. The attenuator 31 adjusts the power output of the laser light L1 coming from the incident portion 12. The beam expander 32 expands the diameter of the laser light L1 whose power output has been adjusted by the attenuator 31. The mirror 33 reflects the laser light L1 whose diameter has been expanded by the beam expander 32.

The adjuster 13 further includes a reflective spatial light modulator 34 and an imaging optical system 35. The reflective spatial light modulator 34 and the imaging optical system 35 of the adjuster 13, and the light-condensing portion 14 are aligned on a straight line (second straight line) A2 extending along the Z direction. The reflective spatial light modulator 34 modulates the laser light L1 reflected by the mirror 33. The reflective spatial light modulator 34 is, for example, a spatial light modulator (SLM) of a liquid crystal on silicon (LCOS) type. The imaging optical system 35 makes up a double-side telecentric optical system in which a reflection surface 34a of the reflective spatial light modulator 34 and an entrance pupil surface 14a of the light-condensing portion 14 have an imaging relationship. The imaging optical system 35 is composed of three or more lenses.

The straight line A1 and the straight line A2 are on a plane perpendicular to the Y direction. The straight line A1 is located closer to the second wall 22 (one wall side) than the straight line A2. In the laser processing head 10A, the laser light L1 coming from the incident portion 12 into the housing 11 travels along the straight line A1, is reflected by the mirror 33 and the reflective spatial light modulator 34 in sequence, proceeds further along the straight line A2, and travels through the light-condensing portion 14 to come out of the housing 11. The order of arrangement of the attenuator 31 and the beam expander 32 may be reverse to the order. The attenuator 31 may be disposed between the mirror 33 and the reflective spatial light modulator 34. The adjuster 13 may include other optical components (e.g., a steering mirror or the like disposed in front of the beam expander 32).

The laser processing head 10A further includes a dichroic mirror 15, a measurement portion 16, an observation portion 17, a driving portion 18, and a circuit 19.

The dichroic mirror 15 is disposed between the imaging optical system 35 and the light-condensing portion 14 on the straight line A2. In other words, the dichroic mirror 15 is disposed between the adjuster 13 and the light-condensing portion 14 in the housing 11. The dichroic mirror 15 is mounted to the optical base 29 on the fourth wall 24 side. The dichroic mirror 15 transmits the laser light L1. From the viewpoint of suppressing astigmatism, the dichroic mirror 15 may be provided as a specific form of dichroic mirror, which is, for example, a cube-shaped one or a dichroic mirror composed of two plates arranged into a twisted positional relationship.

In the housing 11, the measurement portion 16 is disposed closer to the first wall 21 (the side opposite to the one wall side) than the adjuster 13. The measurement portion 16 is mounted to the optical base 29 on the fourth wall 24 side. The measurement portion 16 outputs measurement light L10 for measuring the distance between a surface of the object 100 (e.g., a surface on which the laser light L1 is incident) and the light-condensing portion 14, and detects the measurement light L10 reflected by the surface of the object 100, via the light-condensing portion 14. Specifically, the measurement light L10 outputted from the measurement portion 16 travels through the light-condensing portion 14 and falls on the surface of the object 100. The measurement light L10 reflected by the surface of the object 100 then travels back through the light-condensing portion 14 to reach the measurement portion 16, which detects the reflected measurement light L10.

More specifically, the measurement light L10 outputted from the measurement portion 16 is reflected by the beam splitter 20 and the dichroic mirror 15 in sequence, the beam splitter 20 and dichroic mirror 15 being mounted to the optical base 29 on the fourth wall 24 side, and travels through the light-condensing portion 14 to come out of the housing 11. The measurement light L10 reflected by the surface of the object 100 travels back through the light-condensing portion 14 into the housing 11, is reflected by the dichroic mirror 15 and the beam splitter 20 in sequence, and falls on the measurement portion 16, which detects the reflected measurement light L10.

In the housing 11, the observation portion 17 is disposed closer to the first wall 21 (the side opposite to the one wall side), relative to the adjuster 13. The observation portion 17 is mounted to the optical base 29 on the fourth wall 24 side. The observation portion 17 outputs observation light L20 for observing the surface of the object 100 (e.g., the surface on which the laser light L1 is incident), and detects the observation light L20 reflected by the surface of the object 100, via the light-condensing portion 14. Specifically, the observation light L20 outputted from the observation portion 17 travels through the light-condensing portion 14 and falls on the surface of the object 100. The observation light L20 reflected by the surface of the object 100 then travels back through the light-condensing portion 14 to reach the observation portion 17, which detects the reflected observation light L20.

More specifically, the observation light L20 outputted from the observation portion 17 penetrates through the beam splitter 20, is reflected by the dichroic mirror 15, and travels through the light-condensing portion 14 to come out of the housing 11. The observation light L20 reflected by the surface of the object 100 travels back through the light-condensing portion 14 into the housing 11, is reflected by the dichroic mirror 15, and penetrates through the beam splitter 20 to fall on the observation portion 17, which detects the reflected observation light L20. Respective wavelengths of the laser light L1, the measurement light L10, and the observation light L20 are different from each other (at least their respective center wavelengths are shifted from each other).

The driving portion 18 is mounted to the optical base 29 on the fourth wall 24 side. The driving portion 18 causes the light-condensing portion 14 disposed on the sixth wall 26 to move along the Z direction, by, for example, a driving force of a piezoelectric element.

In the housing 11, the circuit 19 is disposed on the third wall 23 side, with respect to the optical base 29. In other words, in the housing 11, the circuit 19 is disposed closer to the third wall 23 than the adjuster 13, the measurement portion 16, and the observation portion 17. The circuit 19 is, for example, a plurality of circuit boards. The circuit 19 processes a signal outputted from the measurement portion 16 and processes a signal inputted to the reflective spatial light modulator 34 as well. The circuit 19 controls the driving portion 18, based on the signal outputted from the measurement portion 16. For example, based on the signal outputted from the measurement portion 16, the circuit 19 controls the driving portion 18 in such a way as to keep the distance between the surface of the object 100 and the light-condensing portion 14 constant (that is, to keep the distance between the surface of the object 100 and the focusing point of the laser light L1 constant). The housing 11 is provided with a connector (not illustrated) to which wires are connected, the wires electrically connecting the circuit 19 to the controller 9 (see FIG. 1) or the like.

Similar to the laser processing head 10A, the laser processing head 10B includes the housing 11, the incident portion 12, the adjuster 13, the light-condensing portion 14, the dichroic mirror 15, the measurement portion 16, the observation portion 17, the driving portion 18, and the circuit 19. It should be noted, however, that, as shown in FIG. 2, respective components of the laser processing head 10B are arranged plane symmetrical with respective components of the laser processing head 10A, with respect to a virtual plane passing through a midpoint between the pair of fitting portions 65 and 66 and perpendicular to the Y direction.

For example, the housing (first housing) 11 of the laser processing head 10A is fitted to the fitting portion 65 such that the fourth wall 24 is closer to the laser processing head 10B than the third wall 23 and that the sixth wall 26 is closer to the support portion 7 than the fifth wall 25. The housing (second housing) 11 of the laser processing head 10B, on the other hand, is fitted to the fitting portion 66 such that the fourth wall 24 is closer to the laser processing head 10A than the third wall 23 and that the sixth wall 26 is closer to the support portion 7 than the fifth wall 25

The housing 11 of the laser processing head 10B is configured such that the housing 11 is fitted to the fitting portion 66, with the third wall 23 disposed on the fitting portion 66. More specific description is given as follows. The fitting portion 66 has a base plate 66a and a fitting plate 66b. The base plate 66a is fitted on the rails laid on the moving portion 63. The fitting plate 66b is erected on an end of base plate 66a that is closer to the laser processing head 10A. The housing 11 of the laser processing head 10B is fitted to the fitting portion 66, with the third wall 23 kept in contact with the fitting plate 66b. The housing 11 of the laser processing head 10B can be fitted to or removed from the fitting portion 66.

[Advantages and Effects]

According to the laser processing head 10A, the light source that outputs the laser light L1 is not disposed in the housing 11. This allows miniaturization of the housing 11. In the housing 11, the distance between the third wall 23 and the fourth wall 24 is smaller than the distance between the first wall 21 and the second wall 22, and the light-condensing portion 14 disposed on the sixth wall 26 is on the side closer to the fourth wall 24 in the Y direction. As a result, when the housing 11 is moved along the direction perpendicular to the optical axis of the light-condensing portion 14, for example, even if a different component (e.g., the laser processing head 10B) is present on the fourth wall 24 side, the light-condensing portion 14 can be brought closer to the different component. According to the laser processing head 10A, therefore, the light-condensing portion 14 may be moved along the direction perpendicular to the optical axis of the light-condensing portion 14.

In the laser processing head 10A, the incident portion 12 is disposed on the fifth wall 25 such that the incident portion 12 is on the side closer to the fourth wall 24 in the Y direction. As a result, in the area in the housing 11, a different component (e.g., the circuit 19) is disposed in the subarea on the third wall 23 side, relative to the adjuster 13, in which case the subarea can be used effectively.

In the laser processing head 10A, the light-condensing portion 14 is on the side closer to the second wall 22 in the X direction. As a result, when the housing 11 is moved along the direction perpendicular to the optical axis of the light-condensing portion 14, for example, even if a different component is present on the second wall 22 side, the light-condensing portion 14 can be brought closer to the different component.

In the laser processing head 10A, the incident portion 12 is disposed on the fifth wall 25 such that the incident portion 12 is on the side closer to the second wall 22 in the X direction. As a result, in the area in the housing 11, a different component (e.g., the measurement portion 16 and the observation portion 17) is disposed in the subarea on the first wall 21 side, relative to the adjuster 13, in which case the subarea can be used effectively.

In the laser processing head 10A, the measurement portion 16 and the observation portion 17 are disposed in the subarea on the first wall 21 side, relative to the adjuster 13, in the region in the housing 11, the circuit 19 is disposed in the subarea on the third wall 23 side, relative to the adjuster 13, in the region in the housing 11, and the dichroic mirror 15 is disposed between the adjuster 13 and the light-condensing portion 14 in the housing 11. In this manner, the area in the housing 11 can be used effectively. In addition, the laser processing apparatus 1 is allowed to carry out processing based on results of measurement of the distance between the surface of the object 100 and the light-condensing portion 14. The laser processing apparatus 1 is also allowed to carry out processing based on results of observation of the surface of the object 100.

In the laser processing head 10A, the circuit 19 controls the driving portion 18, based on a signal outputted from the measurement portion 16. As a result, the position of the focusing point of the laser light L1 can be adjusted, based on results of measurement of the distance between the surface of the object 100 and the light-condensing portion 14.

In the laser processing head 10A, the incident portion 12, and the attenuator 31, the beam expander 32, and the mirror 33 of the adjuster 13 are aligned on the straight line A1 extending along the Z direction, while the reflective spatial light modulator 34 and the imaging optical system 35 of the adjuster 13, and the light-condensing portion 14 are aligned on the straight line A2 extending along the Z direction. As a result, the adjuster 13 including the attenuator 31, the beam expander 32, the reflective spatial light modulator 34, and the imaging optical system 35 can be configured in a compact form.

In the laser processing head 10A, the straight line A1 is located closer to the second wall 22, relative to the straight line A2. As a result, when a different optical system using the light-condensing portion 14 (e.g., the measurement portion 16 and the observation portion 17) is disposed in the subarea on the first wall 21 side, relative to the adjuster 13, in the area in the housing 11, a degree of freedom in configuring the different optical system can be improved.

The above advantages and effects are achieved also by the laser processing head 10B.

In the laser processing apparatus 1, the light-condensing portion 14 of the laser processing head 10A, the light-condensing portion 14 being on the housing 11 of the laser processing head 10A, is on the side closer to the laser processing head 10B, while the light-condensing portion 14 of the laser processing head 10B, the light-condensing portion 14 being on the housing 11 of the laser processing head 10B, is on the side closer to the laser processing head 10A. As a result, when the pair of laser processing heads 10A and 10B are each moved along the Y direction, the light-condensing portion 14 of the laser processing head 10A and the light-condensing portion 14 of the laser processing head 10B can be brought closer to each other. This allows the laser processing apparatus 1 to process the object 100 efficiently.

In the laser processing apparatus 1, the pair of fitting portions 65 and 66 each move along the Y direction and along the Z direction. As a result, the object 100 can be processed more efficiently.

In the laser processing apparatus 1, the support portion 7 moves along the X direction and along the Y direction, and rotates about the axis, i.e., center line parallel to the Z direction. As a result, the object 100 can be processed more efficiently.

[Modifications]

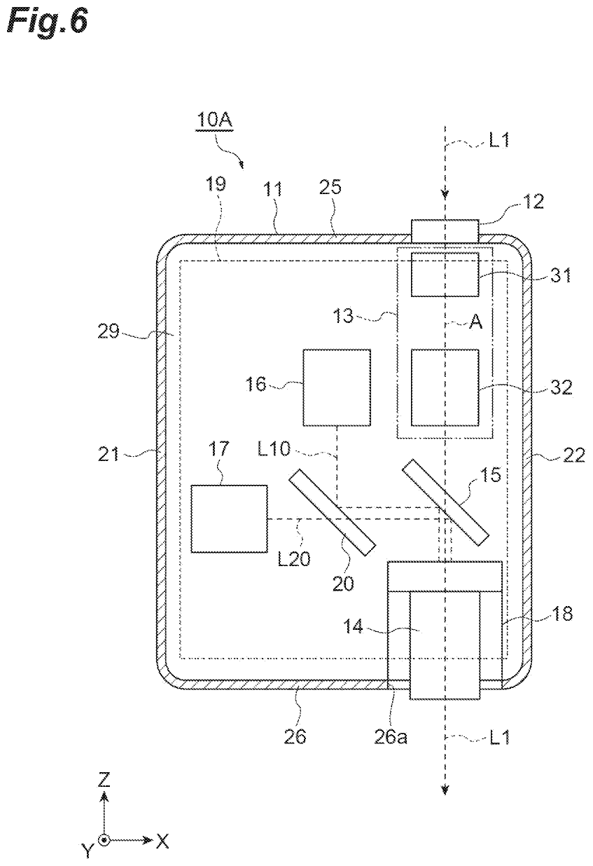

For example, as shown in FIG. 6, the incident portion 12, the adjuster 13, and the light-condensing portion 14 may be aligned on the straight line A extending along the Z direction. This makes the adjuster 13 compact in configuration. In this case, the adjuster 13 may not include the reflective spatial light modulator 34 and the imaging optical system 35. The adjuster 13, however, may include the attenuator 31 and the beam expander 32. This makes the adjuster 13 including the attenuator 31 and the beam expander 32 compact in configuration. The order of arrangement of the attenuator 31 and the beam expander 32 may be reverse to the order.

The housing 11 is configured such that the housing 11 is fitted to the fitting portion 65 (or the fitting portion 66), with at least one of the first wall 21, the second wall 22, the third wall 23, and the fifth wall 25 disposed on the fitting portion 65 (or the fitting portion 66) of the laser processing apparatus 1. The light-condensing portion 14 is at least on the side closer to the fourth wall 24 in the Y direction. According to these arrangements, when the housing 11 is moved along the Y direction, for example, even if a different component is present on the fourth wall 24 side, the light-condensing portion 14 can be brought closer to the different component. In addition, when the housing 11 is moved along the Z direction, for example, the light-condensing portion 14 can be brought closer to the object 100.

The light-condensing portion 14 may be on the side closer to the first wall 21 in the X direction. In this configuration, when the housing 11 is moved along the direction perpendicular to the optical axis of the light-condensing portion 14, for example, even if a different component is present on the first wall 21 side, the light-condensing portion 14 can be brought closer to the different component. In this case, the incident portion 12 may be on the side closer to the first wall 21 in the X direction. In this configuration, in the area in the housing 11, a different component (e.g., the measurement portion 16 and the observation portion 17) is disposed in the subarea on the second wall 22 side, relative to the adjuster 13, in which case the subarea can be used effectively.

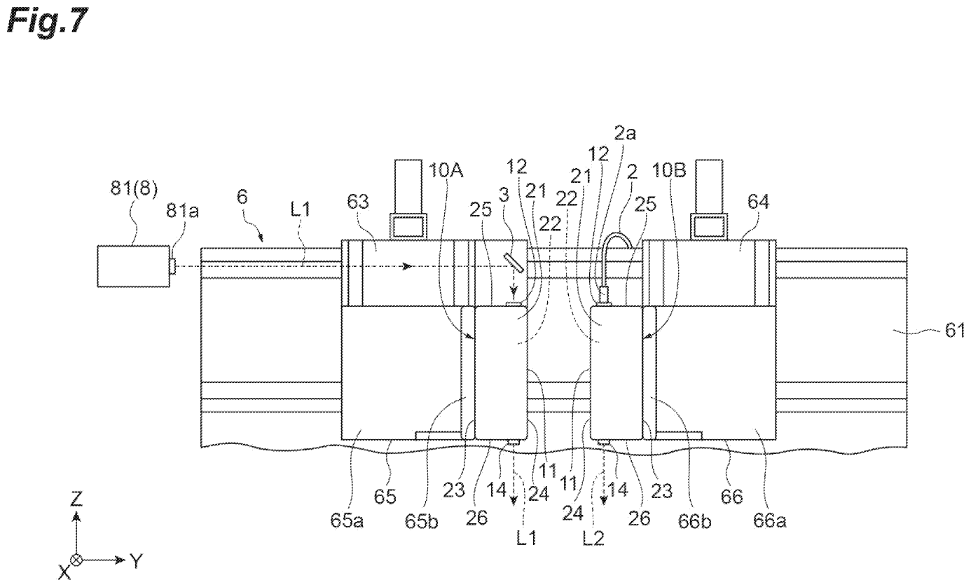

At least one of guiding the laser light L1 from the emitting portion 81a of the light source portion 8 to the incident portion 12 of the laser processing head 10A and guiding the laser light L2 from the emitting portion 82a of the light source portion 8 to the incident portion 12 of the laser processing head 10B may be implemented by a mirror. FIG. 7 is a front view of a part of the laser processing apparatus 1 that guides the laser light L1 by a mirror. In a configuration shown in FIG. 7, a mirror 3, which reflects the laser light L1, is attached to the moving portion 63 of the moving mechanism 6 such that the mirror 3 is counter to the emitting portion 81a of the light source portion 8 in the Y direction and to the incident portion 12 of the laser processing head 10A in the Z direction.

In the configuration shown in FIG. 7, even when the moving portion 63 of the moving mechanism 6 is moved along the Y direction, a state of the mirror 3 being counter to the emitting portion 81a of the light source portion 8 in the Y direction is maintained. In addition, even when the fitting portion 65 of the moving mechanism 6 is moved along the Z direction, a state of the mirror 3 being counter to the incident portion 12 of the laser processing head 10A in the Z direction is maintained. Thus, regardless of the position of the laser processing head 10A, the laser light L1 emitted from the emitting portion 81a of the light source portion 8 can be made incident certainly on the incident portion 12 of the laser processing head 10A. Besides, light guiding by the mirror allows use of a light source with difficulty in light guiding through the optical fiber 2, such as a high-output long/short pulse laser.

In the configuration shown in FIG. 7, the mirror 3 may be attached to the moving portion 63 of the moving mechanism 6 in such way as to allow at least one of angle adjustment and position adjustment of the mirror 3. According to this configuration, the laser light L1 emitted from the emitting portion 81a of the light source portion 8 can be made incident more certainly on the incident portion 12 of the laser processing head 10A.

The light source portion 8 may have one light source. In such a case, the light source portion 8 is configured to let part of the laser light, which is outputted from the one light source, come out of the emitting portion 81a, while letting the rest of the laser light come out of the emitting portion 82b.

The laser processing apparatus 1 may include one laser processing head 10A. In the laser processing apparatus 1 including one laser processing head 10A, when the housing 11 is moved along the Y direction perpendicular to the optical axis of the light-condensing portion 14, for example, even if a different component is present on the fourth wall 24 side, the light-condensing portion 14 can be brought closer to the different component. The laser processing apparatus 1 including one laser processing head 10A is, therefore, able to process the object 100 efficiently. In the laser processing apparatus 1 including one laser processing head 10A, when the fitting portion 65 is moved along the Z direction, the object 100 can be processed more efficiently. In the laser processing apparatus 1 including one laser processing head 10A, when the support portion 7 is moved along the X direction and is rotated about the axis, i.e., center line parallel to the Z direction, the object 100 can be processed more efficiently.

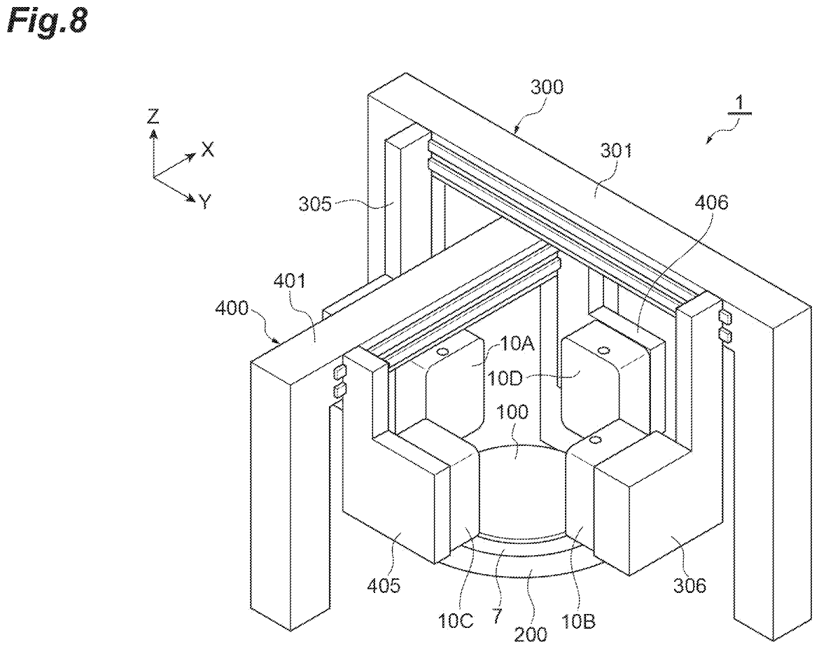

The laser processing apparatus 1 may include three or more laser processing heads. FIG. 8 is a perspective view of a laser processing apparatus 1 including two pairs of laser processing heads. The laser processing apparatus 1 shown in FIG. 8 includes a plurality of moving mechanisms 200, 300, and 400, the support portion 7, a pair of laser processing heads 10A and 10B, a pair of laser processing heads 10C and 10D, and a light source portion (not illustrated).

The moving mechanism 200 moves the support portion 7 along the X direction, the Y direction, and the Z direction, and rotates the support portion 7 about the axis, i.e., center line parallel to the Z direction.

The moving mechanism 300 includes a fixed portion 301, and a pair of fitting portions (a first fitting portion and a second fitting portion) 305 and 306. The fixed portion 301 is mounted to a device frame (not illustrated). The pair of fitting portions 305 and 306 are fitted on rails laid on the fixed portion 301, and are each able to move independently along the Y direction.

The moving mechanism 400 includes a fixed portion 401, and a pair of fitting portions (a first fitting portion and a second fitting portion) 405 and 406. The fixed portion 401 is mounted to the device frame (not illustrated). The pair of fitting portions 405 and 406 are fitted on rails laid on the fixed portion 401, and are each able to move independently along the X direction. The rails of the fixed portion 401 are arranged in such a way as to three-dimensionally cross the rails of the fixed portion 301.

The laser processing head 10A is fitted to the fitting portion 305 of the moving mechanism 300. The laser processing head 10A in a state of being counter to the support portion 7 in the Z direction emits a laser light onto the object 100 supported by the support portion 7. The laser light emitted from the laser processing head 10A is the laser light from a light source portion (not illustrated) that is guided by the optical fiber 2. The laser processing head 10B is fitted to the fitting portion 306 of the moving mechanism 300. The laser processing head 10B in a state of being counter to the support portion 7 in the Z direction emits a laser light onto the object 100 supported by the support portion 7. The laser light emitted from the laser processing head 10B is the laser light from a light source portion (not illustrated) that is guided by the optical fiber 2.

The laser processing head 10C is fitted to the fitting portion 405 of the moving mechanism 400. The laser processing head 10C in a state of being counter to the support portion 7 in the Z direction emits a laser light onto the object 100 supported by the support portion 7. The laser light emitted from the laser processing head 10C is the laser light from a light source portion (not illustrated) that is guided by the optical fiber 2. The laser processing head 10D is fitted to the fitting portion 406 of the moving mechanism 400. The laser processing head 10D in a state of being counter to the support portion 7 in the Z direction emits a laser light onto the object 100 supported by the support portion 7. The laser light emitted from the laser processing head 10D is the laser light from a light source portion (not illustrated) that is guided by the optical fiber 2.

A configuration of the pair of laser processing heads 10A and 10B of the laser processing apparatus 1 shown in FIG. 8 is identical with the configuration of the pair of laser processing heads 10A and 10B of the laser processing apparatus 1 shown in FIG. 1. A configuration of the pair of laser processing heads 10C and 10D of the laser processing apparatus 1 shown in FIG. 8 is identical with a configuration of the pair of laser processing heads 10A and 10B of the laser processing apparatus 1 shown in FIG. 1, the laser processing heads 10A and 10B being rotated by 90 degrees about the axis, i.e., center line parallel to the Z direction.

For example, the housing (first housing) 11 of the laser processing head 10C is fitted to the fitting portion 65 such that the fourth wall 24 is located closer to the laser processing head 10D, relative to the third wall 23, and that the sixth wall 26 is located closer to the support portion 7, relative to the fifth wall 25. The light-condensing portion 14 of the laser processing head 10C is on the side closer to the fourth wall 24 (that is, the side closer to the laser processing head 10D) in the Y direction.

The housing (second housing) 11 of the laser processing head 10D is fitted to the fitting portion 66 such that the fourth wall 24 is located closer to the laser processing head 10C, relative to the third wall 23, and that the sixth wall 26 is located closer to the support portion 7, relative to the fifth wall 25. The light-condensing portion 14 of the laser processing head 10D is on the side closer to the fourth wall 24 (that is, the side closer to the laser processing head 10C) in the Y direction.

In the above configuration, according to the laser processing apparatus 1 shown in FIG. 8, when the pair of laser processing heads 10A and 10B are each moved along the Y direction, the light-condensing portion 14 of the laser processing head 10A and the light-condensing portion 14 of the laser processing head 10B can be brought closer to each other. Similarly, when the pair of laser processing heads 10C and 10D are each moved along the X direction, the light-condensing portion 14 of the laser processing head 10C and the light-condensing portion 14 of the laser processing head 10D can be brought closer to each other

The laser processing heads and the laser processing apparatus are not limited to those for forming modified regions inside the object 100, and may be laser processing heads and a laser processing apparatus for carrying out other forms of laser processing.

An embodiment will then be described. In the following, a description overlapping the description of the above embodiment and modifications will be omitted.

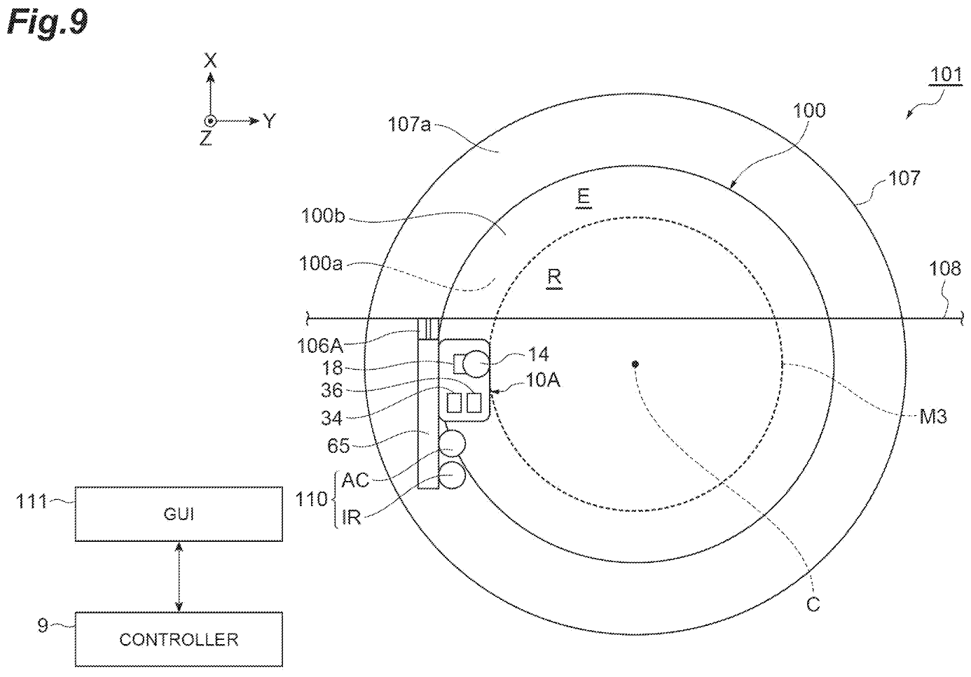

A laser processing apparatus 101 shown in FIG. 9 is a device that emits a laser light onto the object 100, with a focusing position (focusing point, which is at least a part of a focusing region) properly set on the object 100 to form a modified region in the object 100. The laser processing apparatus 101 carries out trimming processing, radiation cutting processing, and peeling processing on the object 100 to obtain (manufacture) a semiconductor device. The trimming processing is processing by which an unnecessary part is removed from the object 100. The radiation cut processing is processing by which the unnecessary part to be removed by the trimming processing is cut apart. The peeling processing is processing by which a part of the object 100 is peeled.

The object 100 is, for example, a semiconductor wafer of a disk shape. The object 100 is not limited to a specific object, and may be a variety of objects made of various materials or having various shapes. Functional elements (not illustrated) are formed on a surface 100a of the object 100. The functional elements are, for example, light-receiving elements, such as photodiodes, light-emitting elements, such as laser diodes, circuit elements, such as memories, or the like.

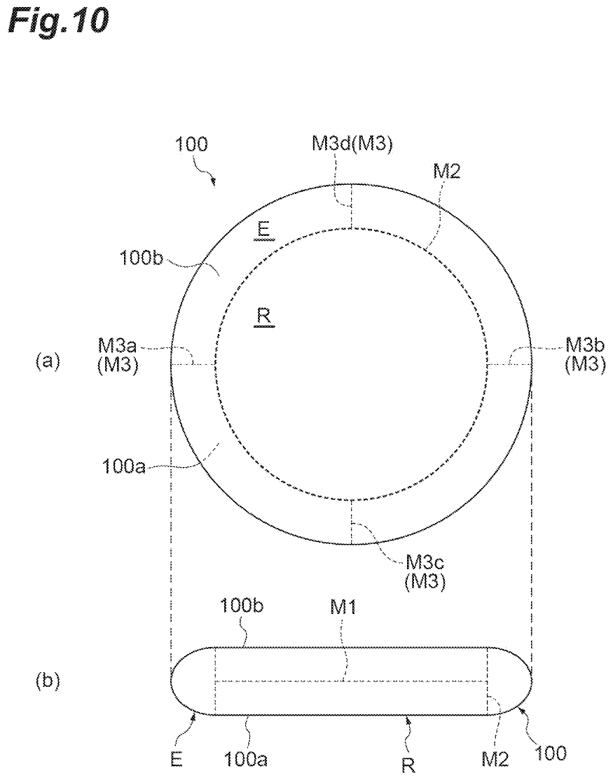

As shown in FIGS. 10(a) and 10(b), an effective area R and a removal area E are set in the object 100. The effective area R is a part corresponding to the semiconductor device to be obtained. The effective area R is a device area. For example, the effective area R is a disc-shaped part including a central part in a view in the direction of thickness of the object 100. The effective area R is an inner area inside the removal area E. The removal area E is an area of object 100 that is outside the effective area R. The removal area E is an outer edge part of object 100 that is different from the effective area R. For example, the removal area E is an annular part encircling the effective area R. The removal area E includes a peripheral part (a bevel part on the outer edge) in a view in the direction of thickness of the object 100. The removal area E is a radiation cut area to be subjected to the radiation cut processing.

In the object 100, a virtual plane M1 is set as a peeling-scheduled plane. The virtual plane M1 is a plane on which a modified region is scheduled to be formed by the peeling processing. The virtual plane M1 is a plane counter to a back surface 100b of the object 100, the back surface 100b being the laser light incident surface. The virtual plane M1 is parallel to the back surface 100b, and is, for example, circular-shaped. The virtual plane M1, which is a virtual area, is not limited to a plain surface but may be a curved surface or a three-dimensional surface. The effective area R, the removal area E, and the virtual plane M1 can be set by the controller 9. The effective area R, the removal area E, and the virtual plane M1 may be set by specifying their coordinates.

In the object 100, a line (annular line) M2 is set as a trimming-scheduled line. The line M2 is a line on which a modified region is scheduled to be formed by the trimming processing. The line M2 extends annularly inside the outer edge of the object 100. The line M2 shown in FIGS. 10(a) and 10(b) extends annually to draw a circle. The line M2 is set along a boundary between the effective area R and the removal area E in a part inside the object 100, the part being opposite to the laser light incident surface with respect to the virtual plane M1. The line M2 can be set by the controller 9. The line M2 is a virtual line, but may be an actually line drawn. The line M2 may be set by specifying its coordinates. This explanation of setting of the line M2 applies also to an explanation of setting of lines M3 and M4, which will be described later.

In the object 100, a line (linear line) M3 is set as a radiation-cut-scheduled line. The line M3 is a line on which a modified region is scheduled to be formed by the radiation cut processing. The line M3 extends linearly (radially) along the direction of radius of the object 100 in a view from the laser light incident surface. A plurality of the lines M3 are set such that the lines M3 divide the removal area E into equal parts (into four parts in FIGS. 10(a) and 10(b)) in the circumferential direction in a view from the laser light incident surface. In the example of FIGS. 10(a) and 10(b), the lines M3 include lines M3a and M3b extending in one direction in a view from the laser light incident surface, and lines M3c and M3d extending in a different direction perpendicular to the one direction.

As shown in FIG. 9, the laser processing apparatus 101 includes a stage 107, the laser processing head 10A, first Z-axis rails 106A, Y-axis rails 108, an imaging-capturing portion 110, a graphical user interface (GUI) 111, and the controller 9. The stage 107 is a support portion that supports the object 100. The stage 107 is similar in configuration to the support portion 7 (see FIG. 1). The object 100 is placed on a support surface 107a of the stage 107 such that the back surface 100b of the object 100 is set on the upper side as the laser light incident surface (i.e., the surface 100a is set on the lower side closer to the stage 107). The stage 107 has a spindle C provided at its center. The spindle C is a shaft extending along the Z direction that is the direction of the optical axis of the light-condensing portion 14. The stage 107 is capable of rotating about the spindle C. The stage 107 is caused to rotate by a driving force of a known driving portion, such as a motor.

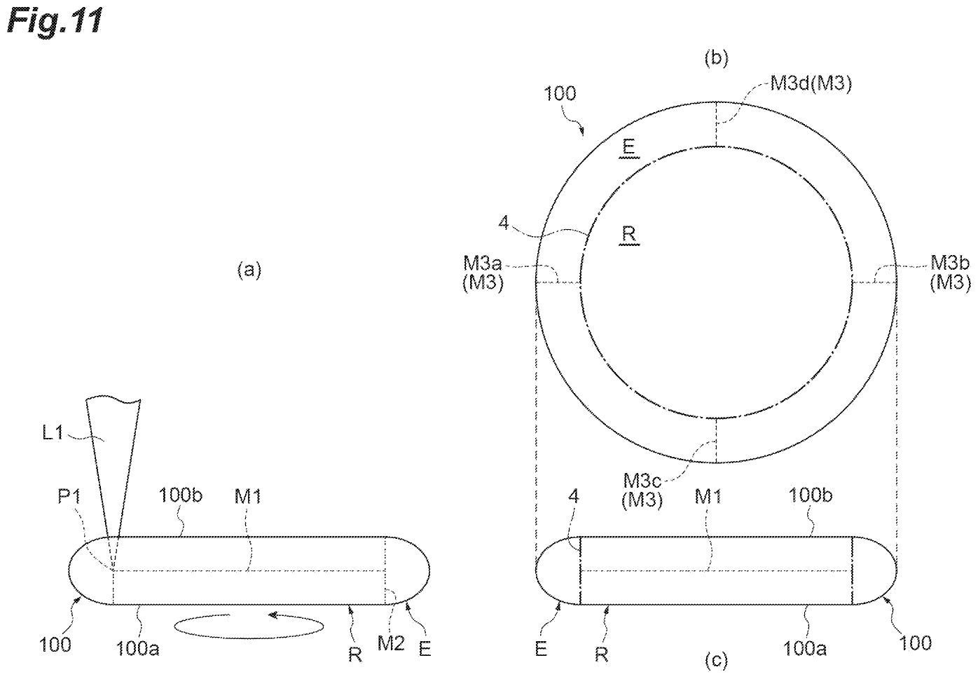

The laser processing head 10A emits the laser light L1 onto the object 100 placed on the stage 107 (see FIG. 11 (a)), via the light-condensing portion 14 along the Z direction to form a modified region inside the object 100. The laser processing head 10A is fitted on the first Z-axis rails 106A and on the Y-axis rails 108. Receiving the driving force of the known driving portion, such as the motor, the laser processing head 10A is able to move linearly along the first Z-axis rails 106A in the Z direction. Receiving the driving force of the known driving portion, such as the motor, the laser processing head 10A is able to move linearly along the Y-axis rails 108 in the Y direction. The laser processing head 10A makes up an emission portion. The light-condensing portion 14 includes a condenser lens.

The laser processing head 10A includes a reflective spatial light modulator 34, and a distance measuring sensor 36. The reflective spatial light modulator 34 makes up a shaping portion that defines the shape of the focusing point (which will hereinafter be referred to also as “beam shape”) in a plane perpendicular to an optical axis of the laser light L1. The reflective spatial light modulator 34 shapes the laser light L1 such that its beam shape has a longitudinal direction. For example, the reflective spatial light modulator 34 displays a modulation pattern on a liquid crystal layer, the modulation pattern making the beam shape into an elliptical shape, thereby reshaping the beam shape into the elliptical shape.

The distance measuring sensor 36 emits a distance measurement laser light onto the laser light incident surface of the object 100, and detects the distance measurement laser light reflected by the laser light incident surface, thereby acquiring displacement data on the laser light incident surface of the object 100. When the optical axis of the distance measuring sensor 36 is different from the optical axis of the laser light L1, a sensor using a triangulation method, a laser confocal method, a white confocal method, a spectral interference method, an astigmatism method, or the like can be adopted as the distance measuring sensor 36. When the optical axis of the distance measuring sensor 36 matches the optical axis of the laser light L1, a sensor using the astigmatic method or the like can be adopted as the distance measuring sensor 36. Based on the displacement data acquired by the distance measuring sensor 36, the circuit 19 (see FIG. 3) of the laser processing head 10A causes the driving portion 18 to move the light-condensing portion 14 in such a way as to make it follow the laser light incident surface. Thus, the light-condensing portion 14 moves along the Z direction, based on the displacement data, such that the distance between the laser light incident surface of the object 100 and the focusing point of the laser light L1 is kept constant. Similarly, other laser processing heads also include such a distance measuring sensor 36 and carry out control based on its data (which will hereinafter be referred to also as “tracking control”).

The first Z-axis rails 106A are rails extending along the Z direction. The first Z-axis rails 106A are fitted to the laser processing head 10A via the fitting portion 65. The first Z-axis rails 106A let the laser processing head 10A move along the Z direction so that the focusing position of the laser light L1 moves along the Z direction (direction intersecting the virtual plane M1). The Y-axis rails 108 are rails extending along the Y direction. The Y-axis rails 108 are fitted to the first Z-axis rails 106 A. The Y-axis rails 108 let the laser processing head 10A move along the Y direction so that the focusing position of the laser light L1 moves along the Y direction (direction along the virtual plane M1). The first Z-axis rails 106A and the Y-axis rails 108 correspond to the rails of the moving mechanism 6 (see FIG. 1) or the rails of the moving mechanism 300 (see FIG. 8). The first Z-axis rails 106A and the Y-axis rails 108 let at least one of the stage 107 and the laser processing head 10A move so that the focusing position of the laser light L1, the focusing position being created by the light-condensing portion 14, moves. Hereinafter, the focusing position of the laser light L1, the focusing position being created by the light-condensing portion 14, will be simply referred to as “focusing position”.

The imaging-capturing portion 110 photographs the object 100 in a direction along the incident direction of the laser light L1. The imaging-capturing portion 110 includes an alignment camera AC and an image-capturing portion IR. The alignment camera AC and the image-capturing portion IR, together with the laser processing head 10A, are fitted to the fitting portion 65. The alignment camera AC captures an image of a device pattern or the like, using, for example, light passing through the object 100. The image obtained by this process is used for alignment of an exposure position of the laser light L1, the exposure position being on the object 100.

The image-capturing portion IR captures an image of the object 100, using light passing through the object 100. For example, when the object 100 is a wafer containing silicon, the image-capturing portion IR uses light in the near-infrared region. The image-capturing portion IR has a light source, an objective lens, and a photodetector. The light source outputs light penetrable to the object 100. The light source is composed of, for example, a halogen lamp and a filter, and outputs, for example, light in the near-infrared region. Light outputted from the light source is guided by an optical system, such as a mirror, to pass through the objective lens, and impinges on the object 100. The objective lens transmits light reflected by the surface of object 100 that is opposite to the laser light incident surface. In other words, the objective lens transmits light having propagated (penetrated) through the object 100. The objective lens has a correction ring. The correction ring, for example, adjusts the distance between a plurality of lenses making up the objective lens, thereby correcting an aberration of light that arises in the object 100. The photodetector detects light having passed through the objective lens. The photodetector is composed of, for example, an InGaAs camera, and detects light in the near-infrared region. The image-capturing portion IR can capture an image of at least one of a modified region formed inside the object 100 and a crack extending from the modified region. In the laser processing apparatus 101, a processing state of laser processing can be checked by a nondestructive method using the image-capturing portion IR.

The GUI 111 displays various pieces of information. The GUI 111 includes, for example, a touch panel display. On the GUI 111, various settings related to processing conditions are entered by a user's operation, such as touching the display. The GUI 111 makes up an input portion that receives the user's input.

The controller 9 is configured as a computer including a processor, a memory, a storage, and a communication device. At the controller 9, software (program) loaded into the memory or the like is executed by the processor, which controls data reading/writing from/to the memory and storage and communications by the communication device. The controller 9 controls respective components of the laser processing apparatus 101, thus implementing various functions.

The controller 9 controls at least the stage 107, the laser processing head 10A, and the moving mechanism 6 (see FIG. 1) or the moving mechanism 300 (see FIG. 1). The controller 9 controls the rotation of the stage 107, emission of the laser light L1 from the laser processing head 10A, and the movement of the focusing position of the laser light L1. The controller 9 can carry out various controls, based on rotation information (which will hereinafter be referred to also as “θ information”) on an amount of rotation of the stage 107. The θ information may be acquired from an extent to which the driving portion causes the stage 107 to rotate, or may be acquired by a separately provided sensor or the like. The θ information can be acquired by various known methods.

While rotating the stage 107, the controller 9 controls the start and stoppage of emission of the laser light L1 from the laser processing head 10A, based on the θ information, as the focusing position is set on the line M2 (the peripheral edge of the effective area R) in the object 100, thereby executing a trimming process of forming a modified region along the peripheral edge of the effective area R. The trimming process is a process the controller 9 executes to carry out the trimming processing.

While keeping the stage 107 from rotating, the controller 9 controls the start and stoppage of emission of the laser light L1 from the laser processing head 10A as the focusing position is set on the line M3 in the object 100, and causes the focusing position of the laser light L1 to move along the line M3, thus executing a radial cut process of forming a modified region along the line M3 in the removal area E. The radiation cut process is a process the controller 9 executes to carry out the radiation cut processing.

While rotating the stage 107, the controller 9 causes the laser processing head 10A to emit the laser light L1 while controlling the movement of the focusing position in the Y direction, thus executing a peeling process of forming a modified region along the virtual plane M1 inside the object 100. The peeling process is process the controller 9 executes to carry out the peeling processing. The controller 9 controls display the GUI 111 makes. The controller 9 executes the trimming process, the radiation cut process, and the peeling process, based on various settings inputted to the GUI 111.

Switching between execution and stoppage of modified region formation is made in the following manner. For example, the laser processing head 10A switches between the start (output) and stoppage of emission of the laser light L1 (that is, switches laser emission on and off), execution and stoppage of modified region formation can be switched. Specifically, when the laser oscillator is composed of a solid-state laser, a Q switch (an AOM or acousto-optic modulator, an EOM or electro-optic modulator, and the like) built in a resonator is switched on and off, which switches the start and stoppage of emission of the laser light L1 at high speed. When the laser oscillator is composed of a fiber laser, a semiconductor laser making up a seed laser and an amplifier (pumping) laser is switched on and off, which switches the start and stoppage of emission of the laser light L1 at high speed. When the laser oscillator uses an external modulation element, the external modulation element (AOM, EOM, etc.) provided outside a resonator is switched on and off, which switches the start and stoppage of emission of the laser light L1 at high speed.

Switching between execution and stoppage of modified region formation may be made in the following manner as well. For example, an optical path for the laser light L1 may be opened and closed by controlling a mechanical mechanism, such as a shutter. This switches execution and stoppage of modified region formation. The laser light L1 may be switched to CW light (continuous wave light), which stops formation of the modified region. A pattern that makes a state of focusing of the laser light L1 a non-reforming state (e.g., a stain-finish pattern that causes laser scattering) may be created on a liquid crystal layer of the reflective spatial light modulator 34. This stops formation of the modified region. A power output adjuster, such as an attenuator, may be controlled to reduce the power output of the laser light L1 to a level at which modified region formation is impossible. This stops formation of the modified region. A polarization direction may be changed in such a way as to stop formation of the modified region. The laser light L1 may be caused to scatter (flick off) in a direction different from the direction of the optical axis to cut off the laser light L1. This stops formation of the modified region.

An example of a laser processing method will then be described, the laser processing method being a method of carrying out the trimming processing, the radiation cutting processing, and the peeling processing on the object 100, using the laser processing apparatus 101, to obtain (manufacture) a semiconductor device.

First, the object 100 with the back surface 100b serving as the laser light incident surface is placed on the stage 107. The surface 100a of the object 100, the surface 100a bearing functional elements, is protected by a support substrate or a tape bonded to the surface 100a.

Subsequently, the trimming processing is carried out. In the trimming processing, the controller 9 executes the trimming process (first process). The trimming processing includes a trimming step (first step). Specifically, in the trimming processing, as the stage 107 is rotated at a constant rotation speed, the start and stoppage of emission of the laser light L1 from the laser processing head 10A is controlled, based on the 0 information, in a state in which the focusing position P1 is set on the line M2, as shown in FIG. 11 (a). As a result, as shown in FIGS. 11(b) and 11(c), a modified region 4 is formed along the line M2. The modified region 4 formed includes a reformed spot and a crack extending from the reformed spot.

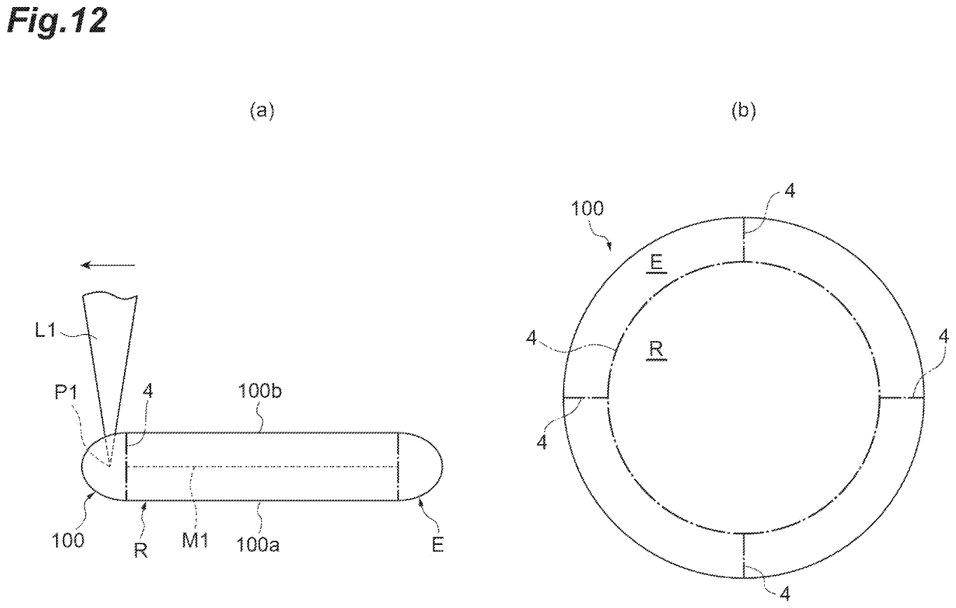

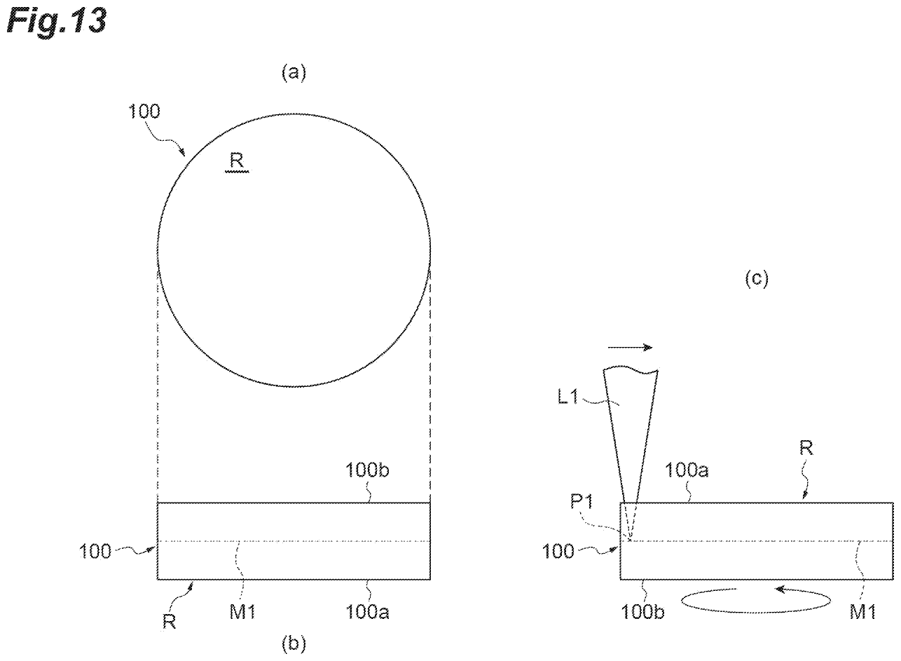

Subsequently, the radiation cut processing is carried out. In the radiation cut processing, the controller 9 executes the radiation cut process (second process). The radiation cut processing includes a radiation cut step (second step). Specifically, in the radiation cut processing, as the stage 107 is kept from rotating, the laser light L1 is emitted from the laser processing head 10A and the laser processing head 10A is moved along the Y-axis rails 108 so that the focusing position P1 moves along the lines M3a and M3b, as shown in FIGS. 11(b) and 12(a). Subsequently, the stage 107 is rotated by 90 degrees and then is kept from rotating again. As the stage 107 is standing still, the laser light L1 is emitted from the laser processing head 10A and the laser processing head 10A is moved along the Y-axis rails 108 so that the focusing position P1 moves along the lines M3c and M3d. As a result, as shown in FIG. 12(b), the modified regions 4 are formed along the lines M3. The modified region 4 formed includes a reformed spot and a crack extending from the reformed spot. The crack may reach at least one of the surface 100a and the back surface 100b, or may not reach at least one of the surface 100a and the back surface 100b. Thereafter, as shown in FIGS. 13(a) and 13(b), the removal areas E are cut away (removed) along the modified regions 4 serving as boundary areas, using, for example, a jig or air blast.

Subsequently, the peeling processing is carried out. Specifically, as the stage 107 is rotated at a constant rotation speed, the laser light L1 is emitted from the laser processing head 10A and the laser processing head 10A is moved along the Y-axis rails 108 so that the focusing position P1 moves along the Y direction, from the outer edge side of the virtual plane M1 to the inside thereof, as shown in FIG. 13 (c). As a result, as shown in FIGS. 13(a) and 13(b), the modified region 4 is formed as a modified region of a spiral shape (involute curve) extending around the position of the spindle C (see FIG. 9) along the virtual plane M1 inside the object 100. The modified region 4 formed includes a plurality of reformed spots.

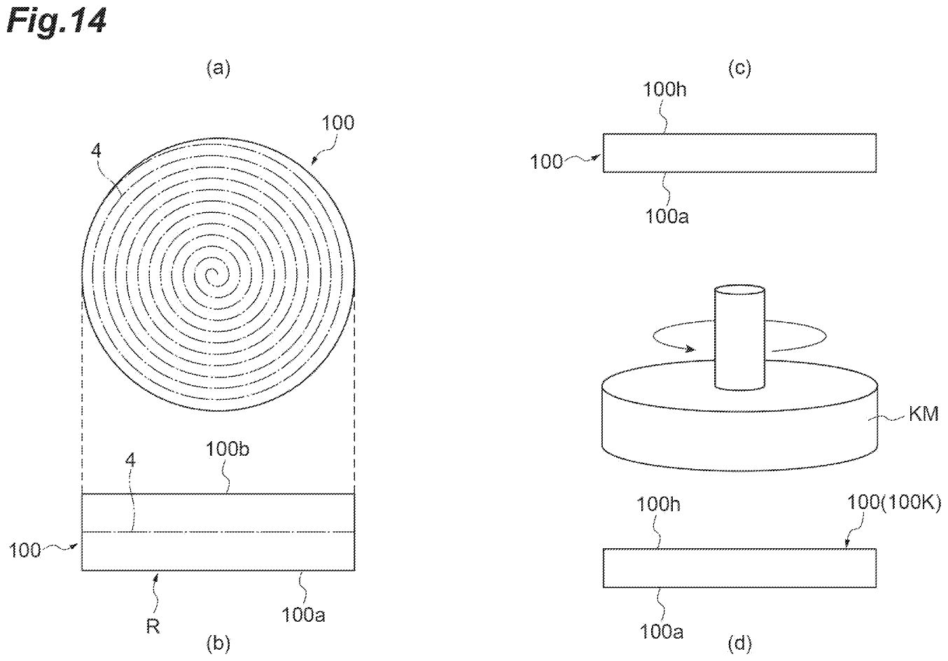

Subsequently, as shown in FIG. 14(c), a part of the object 100 is peeled off along the modified region 4 extending over the virtual plane M1 as a boundary area, using, for example, a suction jig. The part of the object 100 may be peeled off on the stage 107 or in a specific area for the peeling processing after transferring the object 100 thereto. The part of the object 100 may be peeled off by using air blast or a tape. When the part of the object 100 cannot be peeled off solely by an external stress applied thereto, the modified region 4 may be selectively etched with an etching solution (KOH or TMAH) that reacts with the object 100. This allows the part of the object 100 to be peeled off easily. As shown in FIG. 14(d), a peeling surface 100h of the object 100 is subjected to finish grinding or polishing by an abrasive material KM, such as a grindstone. When the part of the object 100 is peeled off by etching, this polishing can be simplified. Through the above processing, a semiconductor device 100K is obtained.

The peeling processing will then be described in detail.

According to the laser processing apparatus 101 and the laser processing method carried out by the laser processing apparatus 101, the laser light with a part of a focusing region being on the object 100 is emitted onto object 100 to form the modified region 4 along the virtual plane M1 inside the object 100. As described above, the laser processing apparatus 101 includes the reflective spatial light modulator 34 serving as the shaping portion that shapes the laser light L1 such that its beam shape has the longitudinal direction.

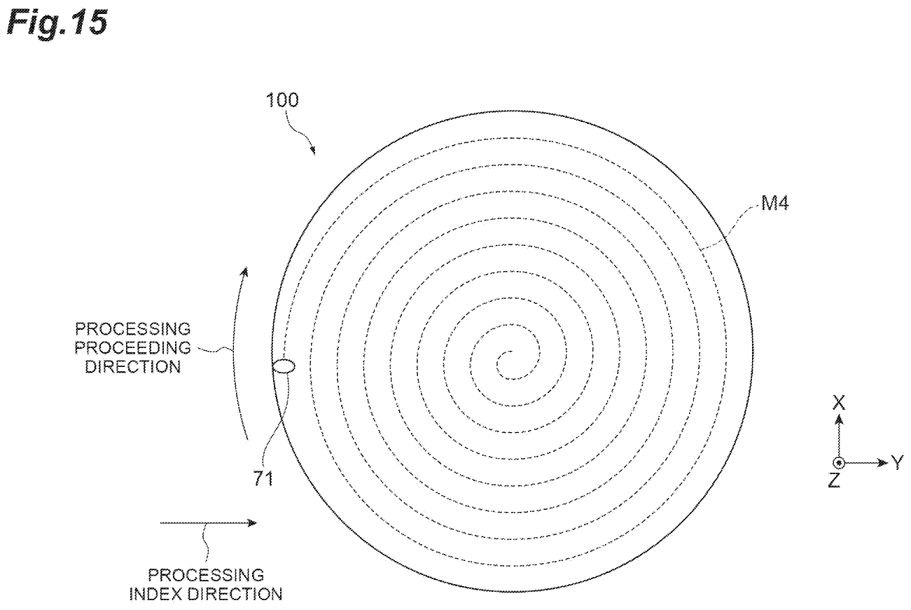

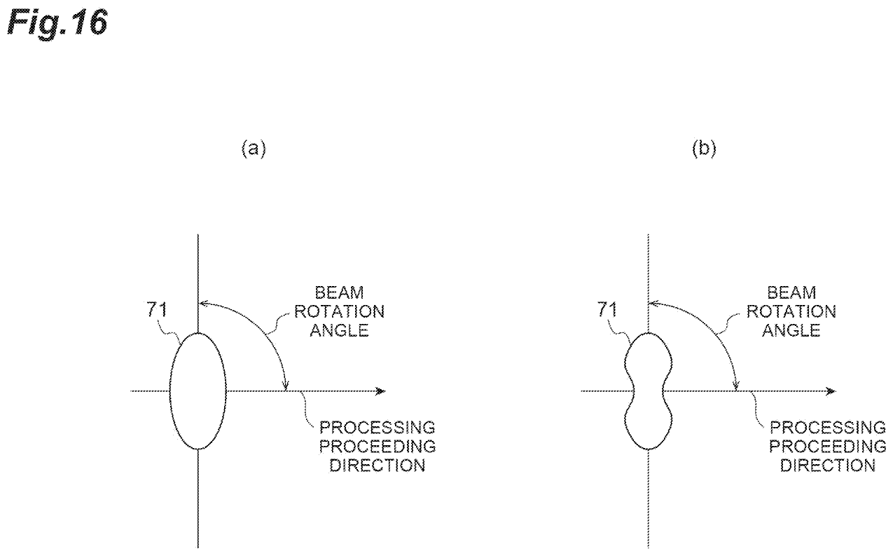

As shown in FIGS. 15 and 16(a), a beam shape 71 created by the reflective spatial light modulator 34 is an elliptical shape. The beam shape 71 is a shape having an ellipticity of 0.88 to 0.95. The ellipticity is the ratio between the length in the longitudinal direction of the beam shape 71 and the length in the latitudinal direction of the same. It should be noted that the beam shape 71 is not limited to an elliptical shape, and may be any type of elongated shape. The beam shape may be a flat circular shape, an oval shape, or a track shape. The beam shape may be an elongated triangular shape, a rectangular shape, or a polygonal shape. For example, the beam shape 71 may be an elliptical shape having its part cut out (see FIG. 16(b)). A modulation pattern of the reflective spatial light modulator 34 that creates such a beam shape 71 may include at least one of a slit pattern the an astigmatic pattern. When the laser light L1 has a plurality of focusing points due to astigmatism or the like, the shape of a focusing point that is on the most upstream side in the optical path of the laser light L1 among the plurality of focusing points may be the beam shape 71 of this embodiment. The longitudinal direction mentioned here is the direction of the major axis of the elliptical shape, i.e., the beam shape 71, and is referred to also as an ellipse major axis direction.

The beam shape 71 of the elliptical shape is a part of the focusing region (the area where the beam focuses). Abeam intensity distribution in the plane of the beam shape 71 shows a high intensity distribution in the longitudinal direction, which means that a direction in which the beam intensity is high matches the longitudinal direction. By adjusting the modulation pattern of the reflective spatial light modulator 34, a position of formation of the beam shape 71 in the Z direction can be controlled in a desired manner. The shaping portion is not limited to the reflective spatial light modulator 34, and may be provided as a slit optical system (including a mechanical slit and the like) or an astigmatic optical system (including a cylindrical lens and the like).

The longitudinal direction the beam shape 71 has is a direction tilted at 45° or more against the processing proceeding direction. The processing proceeding direction is a direction in which the part of the focusing region of the laser light L1 moves. The processing proceeding direction is a direction in which a line M4, which will be described later, extends. Hereinafter, an angle at which the longitudinal direction of the beam shape 71 tilts against the processing proceeding direction will be referred to also as a “beam rotation angle”. In this embodiment, the longitudinal direction the beam shape 71 has is along a direction perpendicular to the processing proceeding direction. In other words, the beam rotation angle is 90°.

The controller 9 controls the reflective spatial light modulator 34 to shape the laser light L1 such that its beam shape has the above-described longitudinal direction. The controller 9 moves the focusing point relatively along the line (processing line) M4 extending spirally inward from a peripheral edge in the object 100 to form the modified region 4 inside the object 100. The line M4 is set in the effective area R on the virtual plane M1. The line M4 extends spirally around the center position of the object 100.

The GUI 111 can receive at least one piece of information out of information on the beam shape 71, information on the beam rotation angle, and information on setting of the reflective spatial light modulator 34, the information being inputted by a user. The controller 9 controls various operations of the laser processing apparatus 101, based on information input to the GUI 111.

In the peeling processing, the stage 107 is rotated at a constant rotation speed, first. The laser processing head 10A then emits the laser light L1 (emission step). At the same time, the laser processing head 10A is moved along the Y-axis rails 108 so that the focusing point of the laser light L1 moves inward from the outer edge of the virtual plane M1 along the Y direction (movement step). Thus, the focusing point of the laser light L1 moves relatively along the line M4. At the emission step, the controller 9 controls the reflective spatial light modulator 34 to shape the laser light L1 such that its beam shape 71 has the longitudinal direction with the beam rotation angle of 90° (shaping step). Through the above steps, the modified region 4 is formed along the line M4 on the virtual plane M1 inside the object 100.

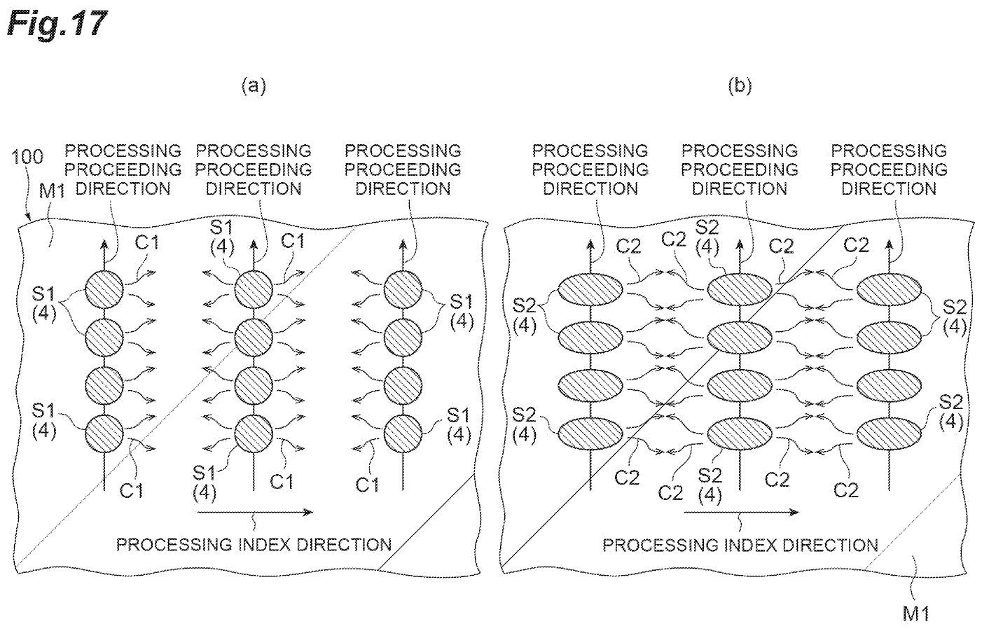

FIG. 17(a) is a diagram for explaining a peeling processing result according to a comparative example in which the laser light of the circular beam shape is used. FIG. 17(b) is a diagram for explaining a peeling processing result according to this embodiment in which the laser light L1 of the elliptical beam shape 71 with the beam rotation angle of 90° is used. FIGS. 17(a) and 17(b) are cross-sectional views of cross sections taken along the virtual plane M1. A processing index direction is a direction that is perpendicular to the direction of extension of the line M4 in a view from the laser light incident surface. The processing index direction is the direction of heading from the peripheral edge of the object 100 toward the inside along the Y direction.

The peeling processing result according to the comparative example demonstrates that circular reformed spots S1 can be formed with less energy. However, as shown in FIG. 17(a), cracks C1 extending from the reformed spots S1 along the virtual plane M1 are hardly connected to each other. The peeling processing result according to this embodiment, in contrast, leads to a finding that reformed spots S2 corresponding to the elliptical shapes of the beam shapes 71 can be formed and that cracks C2 extending from the reformed spots S2 along the virtual plane M1 tend to extend in the longitudinal direction of the reformed spots S2 that corresponds to the longitudinal direction of the beam shapes 71. Since the longitudinal direction is the direction intersecting the processing proceeding direction, the cracks C2 are allowed to readily extend in the direction intersecting the processing proceeding direction, which facilitates spreading of the cracks along the virtual plane M1.

According to this embodiment, therefore, even if intervals between the reformed spots S2 (intervals between the lines M4) in the direction intersecting the processing proceeding direction (the processing index direction in this case) are increased, the cracks C2 can be spread sufficiently along the virtual plane M1. As a result, when the modified region 4 is formed along the virtual plane M1 inside the object 100, a reduction in the tack time can be achieved.

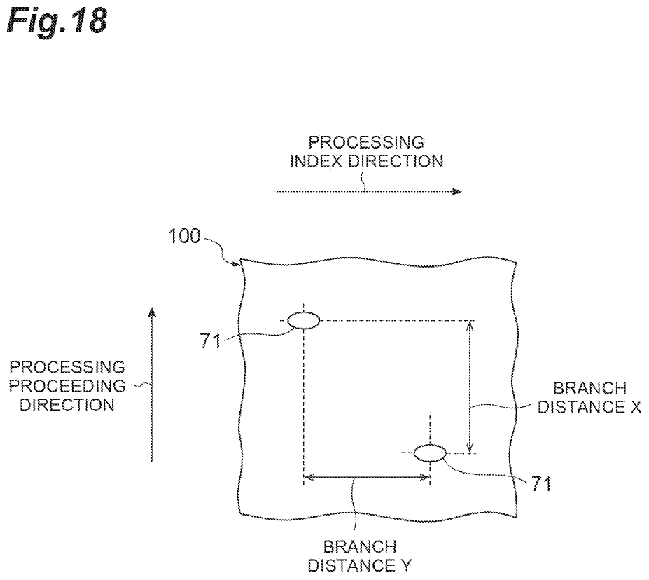

First peeling processing results shown below (see table 1) are the results of the peeling processing according to a first comparative example and a first example. In the first comparative example and the first example, the following conditions are set as common processing conditions. The laser light L1 is branched into two, and a branch distance X and a branch distance Y are determined to be 100 μm and 60 μm, respectively. The branch distance X is the distance in the processing proceeding direction between two beam shapes 71 created by branching the laser light L1 into two, and the branch distance Y is the distance in the processing index direction between the two beam shapes 71 (see FIG. 18). The laser light L1 has its power output set to 3.7 W, pulse energy (a conversion value of the pulse energy assumed to suffer 20% loss by branching) to 18.5 μJ, pulse pitch to 6.25 μm, frequency to 80 kHz, and pulse width to 700 ns. The object 100 is a wafer whose main surface is defined as plane [100] in terms of plane orientation, and its 0° direction corresponds to [110] plane.

[First Peeling Processing Result]

TABLE 1

| | First comparative | |
|---|---|---|
| | example | First example |
| Ellipticity | 0 | 0.95 |
| Beam rotation angle | 0 deg | 90 deg |
| Rate of occurrence of SFC state | 5% | 100% |
| (0-degree direction in object) | | |
| Rate of occurrence of SFC state | 20% | 100% |
| (45-degree direction in object) | | |

SFC state stands for slicing full-cut state. The slicing full-cut state is a state in which cracks extending from a plurality of reformed spots included in the modified region 4 formed along the virtual plane M1 spread along the virtual plane M1 and connect to each other. The slicing full-cut state is a state in which the cracks extending from the reformed spots spread horizontally and vertically and connect to each other across the lines M4 in an image captured by the imaging-capturing portion 110. The slicing full-cut state is a state in which no reformed spots can be confirmed in the image captured by the imaging-capturing portion 110 (a state in which a space or a gap formed by the cracks is confirmed, instead).

It is understood, according to the above first peeling processing results, that by making the beam shape 71 into the shape having the longitudinal direction and setting the longitudinal direction intersecting the processing proceeding direction (e.g., making the beam shape 71 into an elliptical shape and setting the beam rotation angle at 90°), the cracks are allowed to extend more easily in the direction intersecting the processing proceeding direction to facilitate spreading of the cracks along the virtual plane M1, which is advantageous, compared to a case where the beam shape 71 is circular.

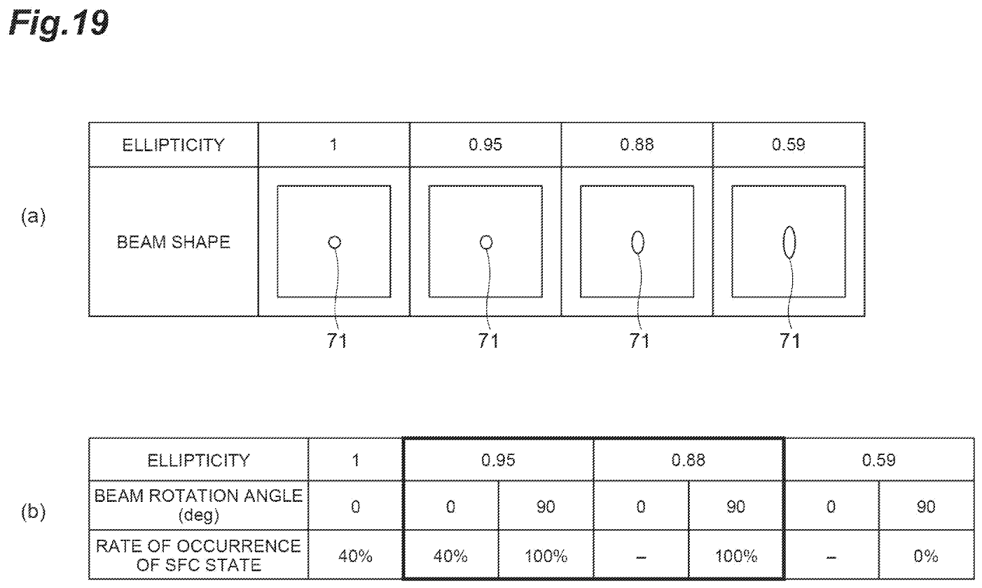

FIG. 19(a) is a table showing a relationship between an ellipticity and the beam shape 71. FIG. 19(b) is a table showing an ellipticity, a beam rotation angle, and a rate of occurrence of a slicing full-cut state. “-” in FIG. 19(b) represents an unmeasurable case. From FIGS. 19(a) and 19(b), it is found that when the ellipticity of the beam shape 71 is smaller than 0.88, the rate of occurrence of the slicing full-cut state is extremely low. For example, when the ellipticity of the beam shape 71 is 0.59, the rate of occurrence of the slicing full-cut state is 0%. When the ellipticity of the beam shape 71 is larger than 0.95, the rate of occurrence of the slicing full-cut state is very low. For example, when the ellipticity of the beam shape 71 is 1 (perfect circle), the rate of occurrence of the slicing full-cut state is 40%.

Based on these findings, according to this embodiment, the part of the focusing region is formed into the shape having the ellipticity of 0.88 to 0.95. As a result, spreading of the cracks along the virtual plane M1 can be further facilitated. The cracks are allowed to extend more easily along the longitudinal direction the beam shape 71 has, and therefore the rate of occurrence of the slicing full-cut state can be increased.

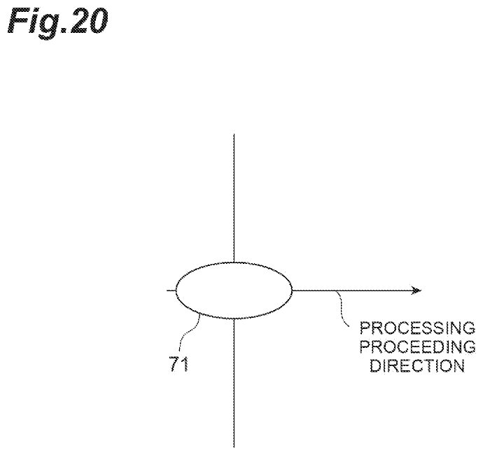

As indicated in FIG. 19(b), when the beam rotation angle of the elliptical beam shape 71 is 0°, the rate of occurrence of the slicing full-cut state is extremely low. When the beam rotation angle of the elliptical beam shape 71 is 90°, on the other hand, it could increase the rate of occurrence of the slicing full-cut state. The case where the beam rotation angle of the elliptical beam shape 71 is 0° is the case where the longitudinal direction of the beam shape 71 is along the processing proceeding direction (see FIG. 20).

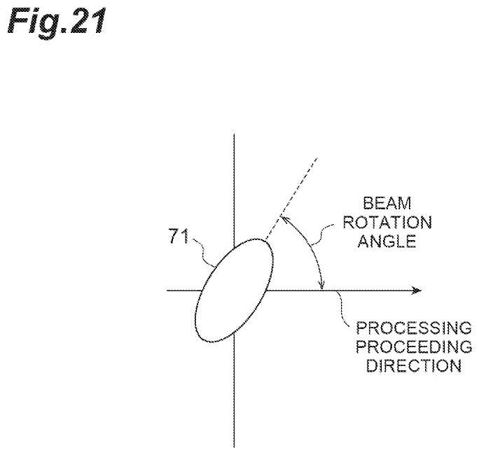

Second peeling processing results shown below (see table 2) are the results of the peeling processing in a case where the beam rotation angle is changed. Common processing conditions of the second peeling processing results are the same as the common processing conditions of the first peeling processing results, except that the pulse pitch is set to 10 μm. The ellipticity is set to 0.95 in the second peeling processing. In the second peeling processing results, for example, the case where the beam rotation angle of the elliptical beam shape 71 is 60° is the case where an angle at which the longitudinal direction of the beam shape 71 tilts against the processing proceeding direction is 60° (see FIG. 21).

[Second Peeling Processing Results]

TABLE 2

| Beam rotation angle | 0 deg | 30 deg | 45 deg | 60 deg | 90 deg |
|---|---|---|---|---|---|
| Rate of occurrence of SFC | 5% | 5% | 5% | 5% | 100% |
| state (0-degree direction in | | | | | |
| object) | | | | | |
| Rate of occurrence of SFC | 5% | 10% | 100% | 100% | 100% |
| state (45-degree direction in | | | | | |
| object) | | | | | |

It is understood, according to the above second peeling processing results, that by setting the beam rotation angle at 45° or more, the cracks are allowed to extend more easily in the direction intersecting the processing proceeding direction to facilitate spreading of the cracks along the virtual plane M1. It is also understood that by setting the beam rotation angle at 90°, the cracks are allowed to extend more easily in the direction intersecting the processing proceeding direction to facilitate spreading of the cracks along the virtual plane M1.

Based on these findings, according to this embodiment, the longitudinal direction of the beam shape 71 is determined to be the direction tilted at 45° or more against the processing proceeding direction. In this case, spreading of the cracks along the virtual plane M1 can be further facilitated. In this embodiment, the longitudinal direction of the beam shape 71 is along the direction perpendicular to the processing proceeding direction. In this case, spreading of the cracks along the virtual plane M1 can be further facilitated.

Third peeling processing results shown below (see table 3 and table 4) are the results of the peeling processing in a case where the pulse pitch is changed. Common processing conditions of the third peeling processing results are the same as the common processing conditions of the first peeling processing results, except that the pulse pitch is changed. The ellipticity is set to 0.95 and the beam rotation angle is set to 90°.

[Third Peeling Processing Results]

TABLE 3

| Pulse pitch | 6.25 μm | 8.125 μm | 8.5 μm | 9 μm |
|---|---|---|---|---|
| Rate of occurrence of SFC state | 100% | 100% | 100% | 100% |
| (0-degree direction in object) | | | | |
| Rate of occurrence of SFC state | 100% | 100% | 100% | 100% |
| (45-degree direction in object) | | | | |

TABLE 4

| Pulse pitch | 9.5 μm | 10 μm | 12.5 μm |
|---|---|---|---|
| Rate of occurrence of SFC state | 100% | 100% | 5% |
| (0-degree direction in object) | | | |
| Rate of occurrence of SFC state | 100% | 100% | 5% |
| (45-degree direction in object) | | | |

It is understood, according to the above third peeling processing results, that by setting the pulse pitch ranging from 6.25 μm to 10 μm, the cracks are allowed to extend more easily in the direction intersecting the processing proceeding direction to facilitate spreading of the cracks along the virtual plane M1.

Fourth peeling processing results shown below (see table 5 and table 6) are the results of the peeling processing in a case where the pulse energy is changed. Common processing conditions of the fourth peeling processing results are the same as the common processing conditions of the second peeling processing results, except that the pulse energy is changed. The ellipticity is set to 0.95 in the second peeling processing.

[Third Peeling Processing Results]

TABLE 5

| Beam rotation angle | 90 deg | 90 deg | 90 deg | 90 deg |
|---|---|---|---|---|
| Pulse energy | 27.7 μJ | 25 μJ | 20 μJ | 18.5 μJ |
| Rate of occurrence of SFC state | 5% | 5% | 30% | 100% |
| (0-degree direction in object) | | | | |
| Rate of occurrence of SFC state | 5% | 40% | 100% | 100% |
| (45-degree direction in object) | | | | |

TABLE 6

| Beam rotation angle | 60 deg | 60 deg | 60 deg | 60 deg |
|---|---|---|---|---|
| Pulse energy | 25 μJ | 20 μJ | 18.5 μJ | 16 μJ |
| Rate of occurrence of SFC state | 5% | 30% | 60% | 30% |
| (0-degree direction in object) | | | | |
| Rate of occurrence of SFC state | 5% | 100% | 100% | 100% |
| (45-degree direction in object) | | | | |

It is understood, according to the above fourth peeling processing results, that by setting the pulse energy to 18.5 μJ (which is larger than 16 μJ and is smaller than 20 μJ), the cracks are allowed to extend more easily in the direction intersecting the processing proceeding direction to facilitate spreading of the cracks along the virtual plane M1.

In this embodiment, the controller 9 relatively moves the part of the focusing region along the line M4 extending spirally inward from the peripheral edge in the object 100 to form the modified region 4 inside the object 100. As a result, a part of the object 100 can be peeled off with high precision along the modified region 4 extending over the virtual plane M1 and the crack extending from the modified region 4, the modified region 4 and crack serving as boundaries.

In this embodiment, the laser processing apparatus is provided with the GUI 111 that can receive at least one pieces of information out of the information on the beam shape 71, the information on the beam rotation angle, and the information on setting of the reflective spatial light modulator 34, the information being inputted by the user. Based on information input to the GUI 111, the controller 9 controls the rotation of the stage 107, emission of the laser L1 from the laser processing head 10A, and the movement of the laser processing head 10A along the Y-axis rails 108. Thus, at execution of the peeling processing, at least one piece of information out of the information on the beam shape 71, the information on the beam rotation angle, and the information on setting of the reflective spatial light modulator 34 can be set as information desired. The beam shape 71, the beam rotation angle, and the like, therefore, can be easily adjusted so as to facilitate spreading of the crack along the virtual plane M1.

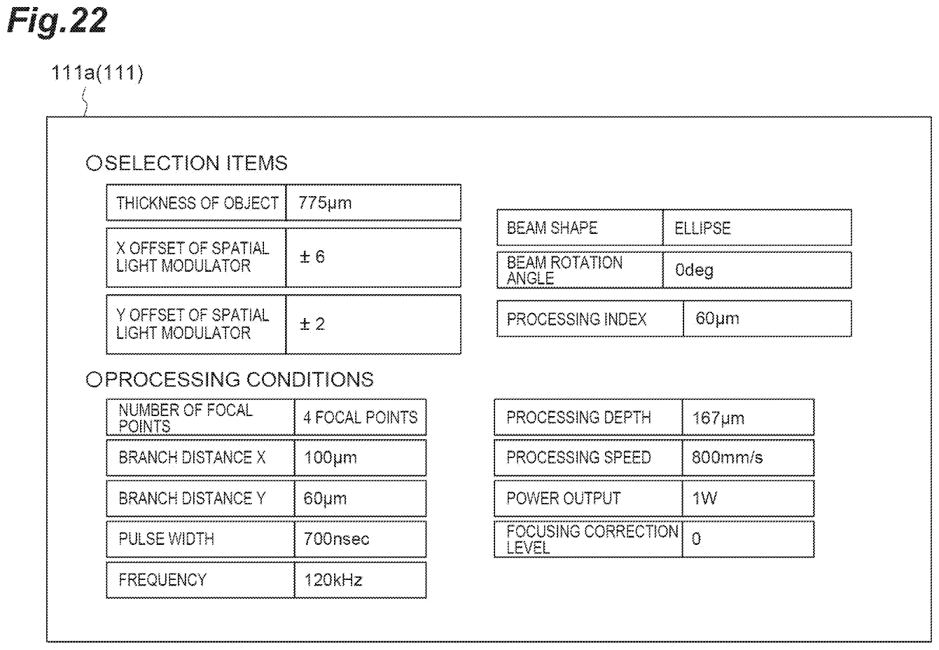

FIG. 22 depicts an example of a setting screen displayed on a touch panel 111a of the GUI 111. The touch panel 111a of the GUI 111 displays various detailed settings and receives input of detailed settings as well. As shown in FIG. 22, setting items displayed on or inputted to the touch panel of the GUI 111 include, for example, the thickness of the object 100, an X offset of the reflective spatial light modulator 34, a Y offset of the reflective spatial light modulator 34, a beam shape, a beam rotation angle, and a processing index. Setting items displayed on or inputted to the touch panel of the GUI 111 further include, for example, the number of focal points, a branch distance X, a branch distance Y, the pulse width of the laser light L1, a frequency, a processing depth, a processing speed, the power output the laser light L1, and a focusing correction level.

The X offset of the reflective spatial light modulator 34 represents a distance by which a reference position of the liquid crystal layer, the reference position being used when a modulation pattern is displayed on the liquid crystal layer, is shifted to an offset position in a given direction. The Y offset of the reflective spatial light modulator 34 represents a distance by which the reference position of the liquid crystal layer, the reference position being used when the modulation pattern is displayed on the liquid crystal layer, is shifted to an offset position in a direction perpendicular to the given direction. The processing index is the distance between a pair of reformed spots adjacent to each other in the processing index direction. The focusing correction level represents a degree of intensity of aberration correction at a processing position. The higher the focusing correction level is, the larger the aberration correction becomes. Various input values are specified by the user, who is allowed to select an intended value from a drop-down menu or select it automatically.

When inputting the beam shape, the user may be allowed to specify or select an ellipse and a perfect circle, to specify or select an ellipticity or a modulation pattern that gives the ellipticity, and to specify or select a modulation pattern intensity. The power output may be the total power output of the laser light L1 or the power output of each of branched beams created by branching the laser light L1. When inputting the branch distance X and the branch distance Y, the user may be allowed to specify the value of the distance or to determine whether or not to set the branch distance X and the branch distance Y.

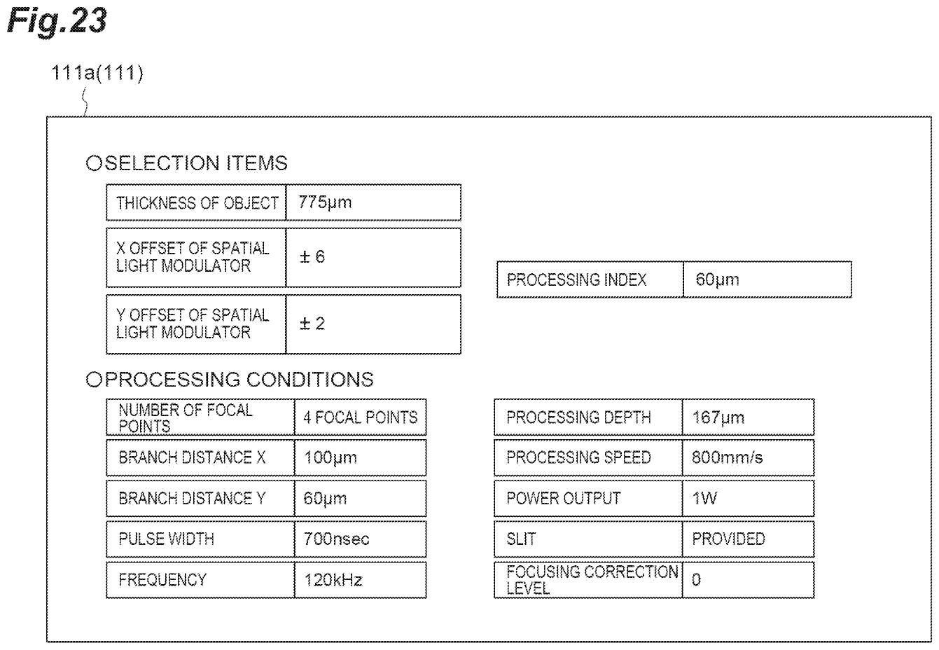

FIG. 23 depicts another example of the setting screen displayed on the touch panel 111a of the GUI 111. As shown in FIG. 23, this example is different from the example shown in FIG. 22 in that setting items displayed on or inputted to the touch panel of the GUI 111 do not include the beam shape and the beam rotation angle and include a slit. The slit is an item corresponding to the shaping portion that shapes the laser light L1 such that its beam shape 71 is of the above-described shape having the longitudinal direction. When inputting the slit, the user may be allowed to determine whether or not to provide the slit or to input or select a slit width by which the desired beam shape 71 is created.

[Modifications]

Aspects of the present invention are not limited to the above-described embodiments.

In the above embodiment, the trimming processing and the radiation cut processing for forming the modified region 4 are carried out before the object 100 is peeled off by the peeling processing. However, the peeling processing, the trimming processing, and the radiation cut processing are carried out in any given order in which any one of them could be first. At least one of the trimming processing and the radiation cut processing may be not executed.

In the above embodiment, at execution of the peeling processing, the spiral line M4 is set as the processing line for forming the modified region 4. The processing line, however, is not limited to the spiral line, and processing lines of various shapes may be set in the object 100. For example, a plurality of linear lines (parallel lines) may be set in the object 100 in such a way as to be lined up in a given direction.

The above embodiment may include a plurality of laser processing heads, as the emission portion. When the plurality of laser processing heads are provided as the emission portion, the above-described laser processing may be carried out using at least one of the plurality of laser processing heads.

In the above embodiment, the reflective spatial light modulator 34 is adopted. The spatial light modulator to be used, however, is not limited to the reflective type, and a transmissive spatial light modulator may also be adopted. In the above embodiment, the type, the shape, and the size of the object 100, the number and direction of crystal orientations the object 100 has, and the plane orientation of the main surface of the object 100 are not particularly limited.

In the above embodiment, the back surface 100b of the object 100 is the laser light incident surface. The surface 100a of the object 100, however, may be adopted as the laser light incident surface. In the above embodiment, the modified region 4 may be, for example, a crystallized area, a recrystallized area, or a gettering area formed inside the object 100. The crystallized area is an area that maintains the structure of the object 100 not subjected to the processing yet. The recrystallized area is an area that after being evaporated, transformed into plasma, or melted, has re-solidified in the form of a single crystal or polycrystal structure. The gettering area is an area that exerts a gettering effect of collecting and capturing impurities, such as heavy metals. The gettering area may be formed continuously or intermittently. The above embodiment may be applied to such processing as ablation.

In the above embodiment, the beam rotation angle is not limited to a specific angle, and may be any angle tilted against the processing proceeding direction. In the above embodiment, the direction of polarization of the laser light L1 emitted onto the object 100 is not limited to a specific direction. The direction of polarization, for example, may be a direction along the processing proceeding direction. The direction of polarization of the laser light L1 can be adjusted by various known techniques.

Components included in the above embodiments and modifications are not limited to the materials and shapes described above. Various materials of different shapes may be used as those components. In addition, components included in the above embodiments or modifications may be used arbitrarily as components making up other embodiments and modifications.

### REFERENCE SIGNS LIST

1, 101 laser processing apparatus
4 modified region
6, 300 moving mechanism
9 controller
10A, 10B laser processing head (emission portion)
34 reflective spatial light modulator (shaping portion)
71 beam shape (the shape of the part of the focusing region)
100 object
100a surface
100b back surface (laser light incident surface)
107 stage (support portion)
108 Y-axis rails (moving mechanism)
111 GUI (input portion)
L1 laser light
M1 virtual plane
M4 line (processing line)

1: A laser processing apparatus configured to emit a laser light with a part of a focusing region being on an object to form a modified region along a virtual plane inside the object, the laser processing apparatus comprising:
a support portion configured to support the object;
an emission portion configured to emit the laser light onto the object;
a moving mechanism configured to move at least one of the support portion and the emission portion so that the part of the focusing region moves along the virtual plane inside the object; and
a controller configured to control the support portion, the emission portion, and the moving mechanism, wherein
the emission portion includes a shaping portion configured to shape the laser light such that a shape of the part of the focusing region in a plane perpendicular to an optical axis of the laser light has a longitudinal direction, and wherein
the longitudinal direction is a direction intersecting a direction of movement of the part of the focusing region.

2: The laser processing apparatus according to claim 1, wherein the longitudinal direction is a direction tilted at 45° or more against a direction of movement of the part of the focusing region.

3: The laser processing apparatus according to claim 1, wherein the longitudinal direction is along a direction perpendicular to a direction of movement of the part of the focusing region.

4: The laser processing apparatus according to claim 1, wherein the part of the focusing region is of a shape with an ellipticity of 0.88 to 0.95.

5: The laser processing apparatus according to claim 1, wherein the controller moves the part of the focusing region relatively along a processing line extending spirally inward from a peripheral edge in the object to form the modified region inside the object.

6: The laser processing apparatus according to claim 1, comprising
an input portion configured to receive at least one piece of information out of information on a shape of the part of the focusing region, information on a tilt against a direction of movement of the part of the focusing region, and information on setting of the shaping portion, the information being inputted by a user, wherein
the controller controls the support portion, the emission portion, and the moving mechanism, based on information input to the input portion.

7: A laser processing method of emitting a laser light with a part of a focusing region being on an object to form a modified region along a virtual plane inside an object, the laser processing method comprising:
an emission step of emitting the laser light onto the object; and
a moving step of moving at least one of a support portion and an emission portion, the support portion configured to support the object and the emission portion emitting the laser light onto the object, so that the part of the focusing region moves along the virtual plane inside the object, wherein
the emission step includes a shaping step of shaping the laser light such that a shape of the part of the focusing region in a plane perpendicular to an optical axis of the laser light has a longitudinal direction, and wherein
the longitudinal direction is a direction intersecting a direction of movement of the part of the focusing region.
